(19) United States
(12) Patent Application Publication
(10) Pub. No.: US 2023/0100663 A1
(43) Pub. Date: Mar. 30, 2023

(54) LUMINOPHORE, METHOD FOR PRODUCING A LUMINOPHORE AND RADIATION-EMITTING COMPONENT

(71) Applicant: ams-OSRAM International GmbH, Regensburg (DE)

(72) Inventors: Dominik BAUMANN, Munich (DE); Markus SEIBALD, Kaufering (DE); Stefan LANGE, Augsburg (DE); Jascha BANDEMEHR, Marburg (DE); Florian KRAUS, Marburg (DE)

(21) Appl. No.: 17/911,445

(22) PCT Filed: Mar. 15, 2021
(86) PCT No.: PCT/EP2021/056526

§ 371 Date: Sep. 14, 2022

(30) Foreign Application Priority Data
Mar. 16, 2020 (DE) 10 2020 203 329.3

(51) Int. Cl. C09K 11/67; C09K 11/66; H01L 33/50

(52) U.S. Cl. CPC C09K 11/675; C09K 11/665; C09K 11/664; C09K 11/674; H01L 33/504

(57) ABSTRACT

A luminophore may have the general formula A_{z}EₑX₆:RE, where A is selected from bivalent elements, E is selected from tetravalent elements, X is selected from monovalent elements, and RE is selected from activator elements. In addition, 0.9≤z≤1.1, and 0.9≤e≤1.1. A method for producing such a luminophore is also disclosed. A radiation-emitting component may further include the luminophore.

### CROSS-REFERENCE TO RELATED APPLICATIONS

The present application is a national stage entry according to 35 U.S.C. § 371 of PCT application No.: PCT/EP2021/056526 filed on Mar. 15, 2021; which claims priority to German patent application DE 10 2020 203 329.3, filed on Mar. 16, 2020; all of which are incorporated herein by reference in their entirety and for all purposes.

### TECHNICAL FIELD

A luminophore and a process for producing a luminophore are specified. Additionally specified is a radiation-emitting component.

### BACKGROUND

One problem addressed is that of specifying a luminophore having elevated efficiency. Further problems addressed are a process for producing a luminophore having elevated efficiency, and a radiation-emitting component having elevated efficiency.

### SUMMARY

A luminophore is specified. In at least one embodiment, the luminophore has the general formula A_{z}EₑX₆:RE where
A is selected from the group of the divalent elements,
E is selected from the group of the tetravalent elements,
X is selected from the group of the monovalent elements,
RE is selected from activator elements,
0.9≤z≤1.1 and
0.9≤e≤1.1.

Here and hereinafter, luminophores are described by empirical formulae. The elements listed in empirical formulae are in charged form. Here and hereinafter, elements or atoms in relation to the empirical formula of the luminophores thus mean ions in the form of cations and anions, even if this is not stated explicitly. This is also true of element symbols if these are specified without their charge for the sake of clarity.

It is possible in the empirical formula specified that the luminophore includes further elements, for example in the form of impurities. Collectively, these impurities comprise not more than 5 mol %, especially not more than 1 permille, especially not more than 100 ppm (parts per million), preferably not more than 10 ppm.

In at least one embodiment, the luminophore comprises a mixture. The mixture comprises the general formula A_{z}EₑX₆:RE or consists of the general formula A_{z}EₑX₆:RE. Further constituents of the mixture may, for example, the reactants that have not reacted in the course of preparation of the luminophore, impurities and/or secondary phases that are formed in the reaction.

The term “valency” in relation to a particular element in the present context means how many elements having a single opposite charge are required in a chemical compound to achieve balancing of the charge. Thus, the term “valency” encompasses the charge of the element.

Elements having a valency of two are referred to as divalent elements. Divalent elements are frequently doubly positively charged in chemical compounds and have a charge of +2. Balancing of the charge in a chemical compound may take place, for example, by means of two further elements that are each singly negatively charged, or one element which is doubly negatively charged. Divalent elements in the present context are generally selected from the group formed by alkaline earth metals and elements of the transition groups.

Tetravalent elements are elements having a valency of four. Tetravalent elements are frequently quadruply positively charged in chemical compounds and have a charge of +4. Balancing of the charge in a chemical compound may take place, for example, by means of one element which is quadruply negatively charged, by means of two elements that are doubly negatively charged, or four elements that are each singly negatively charged. Tetravalent elements in relation to E in the present context are generally selected from the group formed by silicon, germanium, tin, lead, titanium, zirconium and hafnium.

Monovalent elements are elements having a valency of one. Monovalent elements in chemical compounds may be singly negatively charged and have a charge of −1. The monovalent elements serve to balance the charge of the cations. Monovalent elements in the present context are generally selected from the group formed by the halogens. The present luminophore had a total of six monovalent anions.

The present luminophore may be in outwardly uncharged form. This means that there may be outwardly complete balancing of charge between positive and negative charges in the luminophore. By contrast, it is also possible that the luminophore formally does not have complete balancing of charge to a minor degree.

Such a luminophore can convert electromagnetic radiation of a particular wavelength or particular wavelength range, referred to hereinafter as primary radiation, to electromagnetic radiation of a second wavelength or second wavelength range, referred to hereinafter as secondary radiation. The conversion of primary radiation to secondary radiation is also referred to as wavelength conversion. In particular, wavelength conversion involves absorption of primary radiation by a wavelength-converting element that contains a luminophore, conversion thereof to secondary radiation by electronic processes at the atomic and/or molecular level, and emission again. Primary and secondary radiation thus have at least partly different wavelength ranges, with secondary radiation, in one embodiment, having a longer-wave wavelength range than the primary radiation. In particular, pure scatter or pure absorption of electromagnetic radiation is not what is meant by the term “wavelength conversion” in the present context.

A luminophore as described here—according to the application and type of radiation-emitting component—may preferably be used for generation of a low correlated color temperature (CCT), with a high color rendering index Rₐ (CRI), of cold white, warm white or red light, for example in display applications and general lighting. By comparison with conventionally used red-emitting luminophores, for example K₂SiF₆:Mn, SrLiAl₃N₄:Eu or (Sr,Ca)AlSiN₃:Eu, which firstly have a very high spectral half-height width and/or secondly have emission bands in the long-wave red wavelength range, the light yield or luminous efficiency of the present luminophore is elevated on account of its narrowband emission, i.e. emission with a low spectral half-height width. Narrowband luminophores produce comparatively few photons in the deep red spectral region, which are perceived only very inefficiently by the human eye, while the red color impression of the light is simultaneously maintained.

The present luminophore also has an improved luminous efficacy of radiation. The quotient of luminous flux of the radiation and the radiant power thereof is referred to as luminous efficacy of radiation (LER). The greater the luminous efficacy of radiation, the greater the luminous flux utilizable by the eye at a given power. Thus, the spectral position of the emission of the luminophore described here has an extremely strong influence on the total luminous efficacy of radiation. Even small shifts in the emission maximum of otherwise identical emission bands lead to improvements in efficiency by up to 13%.

In the case of the luminophore described here, there is advantageously no use of hydrofluoric acid for production. By comparison, for example, K₂SiF₆:Mn is prepared industrially via a process in which large amounts of aqueous or concentrated hydrofluoric acid solutions are used. On account of the toxicity and difficulty of handling hydrofluoric acid, this entails very complex safety precautions. The luminophore described here is especially produced in a dry high-temperature process.

In one embodiment, the luminophore comprises a crystalline, for example ceramic, host lattice into which foreign elements are introduced as activator elements. The luminophore is, for example, a ceramic material.

The host lattice changes the electronic structure of the activator element in that primary radiation can be absorbed by the luminophore. The primary radiation can induce an electronic transition in the activator element, which can be converted back to the ground state with emission of secondary radiation. The activator element introduced into the host lattice is thus responsible for the wavelength-converting properties of the luminophore.

The crystalline host lattice is especially constructed from a generally three-dimensionally periodically repeating unit cell. In other words, the unit cell is the smallest repeating unit of the crystalline host lattice. The elements A, E and X each occupy positions therein, called point positions, within the unit cell of the host lattice. For example, the activator element RE and the tetravalent element E have equivalent point positions, or point positions in immediate proximity.

Description of the three-dimensional unit cell of the crystalline host lattice requires six lattice parameters: three lengths a, b and c, and three angles α, β and γ. The three lattice parameters a, b and c are the lengths of the lattice vectors that form the unit cell. The further three lattice parameters α, β and γ are the angles between these lattice vectors. α is the angle between b and c, β is the angle between a and c, and γ is the angle between a and b. V corresponds here to the volume of the unit cell.

In one embodiment, the luminophore has the general formula A_{z}EₑX₆:RE where
A is selected from Ca, Sr, Ba, Zn, Mg, Cd or combinations thereof,
E is selected from Hf, Ge, Sn, Pb or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}HfₑX₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}HfₑF₆:RE where
A is selected from Ca, Sr, Ba, Zn, Mg, Cd or combinations thereof,
RE is selected from activator elements,
0.9≤e≤1.1. Preferably, e=1 and z=1.

In at least one embodiment, the luminophore has the general formula A_{z}HfₑF₆:RE where
A is selected from Ca, Zn, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}GeₑX₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}GeₑF₆:RE where
A is selected from Ca, Sr, Ba, Zn, Mg, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}GeₑF₆:RE where
A is selected from Ca, Zn, Cd or combinations thereof,
RE is selected from activator elements,
0.9≤z≤1.1 and
0.9≤e≤1.1. Preferably, e=1 and z=1.

The luminophore in this embodiment does not include any toxic heavy metals, for example cadmium or lead. The use of these heavy metals in electronic components is strictly limited by the legislator within the scope of RoHS guidelines.

In at least one embodiment, the luminophore has the general formula A_{z}SnₑX₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}SnₑF₆:RE where
A is selected from Ca, Sr, Ba, Zn, Mg, Cd or combinations thereof,
RE is selected from activator elements,
0.9≤z≤1.1 and
0.9≤e≤1.1. Preferably, e=1 and z=1.

Advantageously, the luminophore of the formula A_{z}SnₑF₆:RE may have a significantly higher luminous efficacy of radiation than the comparatively luminophore K₂SiF₆:Mn.

In at least one embodiment, the luminophore has the general formula A_{z}SnₑF₆:RE where
A is selected from Ca, Zn, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}PbₑX₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}PbₑF₆:RE where
A is selected from Ca, Sr, Ba, Zn, Mg, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}PbₑF₆:RE where
A is selected from Ca, Zn, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}EₑX₆:RE where
A is selected from Ca, Sr, Ba, Zn, Mg, Cd or combinations thereof,
E is selected from Ti, Zr, Hf, Ge, Sn, Pb or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}TiₑF₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}TiₑF₆:RE where
A=Sr,
RE is selected from activator elements,
0.9≤z≤1.1 and
0.9≤e≤1.1. Preferably, e=1 and z=1.

In at least one embodiment, the luminophore has the general formula A_{z}ZrₑF₆:RE where
A is selected from Ca, Sr, Ba, Zn, Mg, Cd or combinations thereof,
X is selected from F, Cl, Br, I or combinations thereof,
RE is selected from activator elements,
0.9≤z≤1.1 and
0.9≤e≤1.1.

In at least one embodiment, the luminophore has the general formula A_{z}ZrₑF₆:RE where
A is selected from Ca, Sr, Ba, Zn, Mg, Cd or combinations thereof,
RE is selected from activator elements,
0.9≤z≤1.1 and
0.9≤e≤1.1. Preferably, e=1 and z=1.

In at least one embodiment, the luminophore has the general formula A_{z}ZrₑF₆:RE where
A is selected from Ca, Zn or combinations thereof,
RE is selected from activator elements,
0.9≤z≤1.1 and
0.9≤e≤1.1. Preferably, e=1 and z=1.

The luminophore in this embodiment advantageously does not include any toxic heavy metals, for example cadmium or lead. The luminophore is suitable, for example, as an alternative to quantum dots, the use of which is subject to strict requirements as a result of the cadmium used within the scope of RoHS guidelines.

In at least one embodiment, X is selected from F, Cl, Br, I or combinations thereof. In at least one embodiment, X comprises or consists of F. These elements are readily available.

In at least one embodiment, RE is selected from Mn, Cr, Ni, Eu, Ce or combinations thereof. RE is preferably selected from Mn, Cr, Ni or combinations thereof. In at least one embodiment, RE consists of Mn, Cr or Ni.

In at least one embodiment, RE comprises manganese. In at least one embodiment, RE consists of manganese. This is especially in the Mn⁴⁺ form.

In at least one embodiment, the activator element RE has a molar proportion between 0.001 and 0.1 or 0.2 inclusive, based on E. In other words, between 0.1% and 10% or 20% inclusive of the point positions are substituted by RE. In particular, the molar proportion of RE based on E is between 0.005 and 0.5 inclusive, or between 0.01 and 0.10 inclusive.

In at least one embodiment, A is selected from Ca, Sr, Ba, Cd, Zn, Mg or combinations thereof. The luminophore preferably has a host lattice comprising AX₆ octahedra and EX₆ octahedra that are linked by a common X atoms.

The AX₆ octahedra and EX₆ octahedra are each formed by the X atoms. The AX₆ octahedra and EX₆ octahedra may have an octahedral vacancy. The octahedral vacancy is a region within the respective octahedron. For example, the term “octahedral vacancy” refers to the region within the octahedron which is unoccupied when touching spheres, i.e. X atoms, are placed at the vertices of the octahedron. The X atoms of the AX₆ octahedra or of the EX₆ octahedra form the octahedra, with the A or E atom present in the octahedral vacancy of the octahedron formed. More particularly, E is partly replaced by RE. In other words, the octahedron is centered around the E atom or the E atom. The A atom or the E atom are surrounded octahedrally by six X atoms. More particularly, all the atoms that form the octahedron have a similar distance from the A atom or E atom present in the octahedral vacancy. The X atom that joins the AX₆ octahedron to the EX₆ octahedron is a common X atom between the two octahedra. More particularly, every X atom of the octahedron is joined to a further octahedron. More particularly, the AX₆ octahedra and EX₆ octahedra are arranged alternately in particular spatial directions.

In at least one embodiment, the luminophore has the same crystal structure as CaZrF₆, CaHfF₆, ZnHfF₆, CaPbF₆, SrSnF₆, CdHfF₆, ZnZrF₆, CaGeF₆, ZnSnF₆, MgGeF₆, CdPbF₆, ZnPbF₆, MgPbF₆, CaSnF₆ or BaPbF₆.

In at least one embodiment, the luminophore crystallizes in the cubic Fm3̅m space group (number 225), in the trigonal R3̅ space group (number 148) or in the trigonal R3̅m space group (number 166). For example, the luminophores having the formula CaZrF₆:Mn, CaHfF₆:Mn, CaPbF₆:Mn, SrSnF₆:Mn, CdHfF₆:Mn, ZnZrF₆:Mn and CaSnF₆:Mn crystallize in the Fm3̅m space group, the luminophores having the formula ZnHfF₆:Mn, CaGeF₆:Mn, ZnSnF₆:Mn, MgGeF₆:Mn, CdPbF₆:Mn, ZnPbF₆:Mn and mgPbF₆:Mn in the R3̅ space group, and the luminophore BaPbF₆ in the R3̅m space group.

In at least one embodiment, the luminophore has the formula CaHfF₆:RE. In one embodiment, RE here is Mn⁴⁺. Such a luminophore does not include any toxic heavy metals. In addition, the luminophore has a luminous efficacy of radiation up to 10% higher compared to comparative luminophores, for example K₂SiF₆:Mn⁴⁺.

In at least one embodiment, the luminophore has the formula CaZrF₆:RE. In one embodiment, RE here is Mn⁴⁺. Such a luminophore does not include any toxic heavy metals. In addition, the luminophore has a luminous efficacy of radiation up to 10% higher compared to comparative luminophores, for example K₂SiF₆:Mn⁴⁺.

In at least one embodiment, the luminophore has the formula SrTiF₆:RE. In one embodiment, RE here is Mn⁴⁺. Such a luminophore does not include any toxic heavy metals. In addition, the luminophore has an efficiency gain when used in a radiation-emitting component, and simultaneously improved color rendering.

In at least one embodiment, the luminophore has the formula ZnHfF₆:RE. In one embodiment, RE here is Mn⁴⁺. Such a luminophore does not include any toxic heavy metals.

In at least one embodiment, the luminophore has the formula CaGeF₆:RE. In one embodiment, RE here is Mn⁴⁺. Such a luminophore does not include any toxic heavy metals.

In at least one embodiment, the luminophore has the formula CaPbF₆:RE. In one embodiment, RE here is Mn⁴⁺. Such a luminophore does not include any toxic heavy metals. In addition, the luminophore has a luminous efficacy of radiation up to 5% higher compared to comparative luminophores, for example K₂SiF₆:Mn⁴⁺.

In at least one embodiment, the luminophore has the formula BaPbF₆:RE. In one embodiment, RE here is Mn⁴⁺.

In at least one embodiment, the luminophore has the formula ZnZrF₆:RE. In one embodiment, RE here is Mn⁴⁺. Such a luminophore does not include any toxic heavy metals. In addition, the luminophore has a luminous efficacy of radiation comparable to the comparative luminophore K₂SiF₆:Mn⁴⁺.

In at least one embodiment, the luminophore has the formula MgGeF₆:RE. In one embodiment, RE here is Mn⁴⁺. Such a luminophore does not include any toxic heavy metals.

In at least one embodiment, the luminophore has the formula CdPbF₆:RE. In one embodiment, RE here is Mn⁴⁺. Such a luminophore does not include any toxic heavy metals. In addition, the luminophore has a luminous efficacy of radiation up to 5% higher compared to comparative luminophores, for example K₂SiF₆:Mn⁴⁺.

In at least one embodiment, the luminophore has the formula ZnPbF₆:RE. In one embodiment, RE here is Mn⁴⁺.

In at least one embodiment, the luminophore has the formula MgPbF₆:RE. In one embodiment, RE here is Mn⁴⁺. Such a luminophore has a slightly higher luminous efficacy of radiation compared to the comparative luminophore K₂SiF₆:Mn⁴⁺.

In at least one embodiment, the luminophore has the formula CdHfF₆:RE. In one embodiment, RE here is Mn⁴⁺.

In at least one embodiment, the luminophore has the formula ZnZrF₆:RE. In one embodiment, RE here is Mn⁴⁺. Such a luminophore does not include any toxic heavy metals.

In at least one embodiment, the luminophore has the formula CaSnF₆:RE. In one embodiment, RE here is Mn⁴⁺. Such a luminophore does not include any toxic heavy metals. In addition, the luminophore has a luminous efficacy of radiation up to 15% higher compared to comparative luminophores, for example K₂SiF₆:Mn⁴⁺.

In at least one embodiment, the luminophore is in particle form, especially with grain sizes between 0.1 micrometer and 100 micrometers inclusive.

In at least one embodiment, local maxima in the excitation spectrum of the luminophore are between 320 nanometers and 420 nanometers inclusive, and between 430 nanometers and 550 nanometers inclusive. This means that the luminophore absorbs primary radiation in the near UV region and in the blue wavelength region. Thus, the luminophore is suitable for use in a radiation-emitting component with blue and/or near-UV primary radiation.

In at least one embodiment of the luminophore, an emission spectra measured between 600 nanometers and 700 nanometers has a multitude of emission peaks. The luminophore thus converts primary radiation, especially primary radiation in the blue wavelength region, to secondary radiation in the red wavelength region. The multitude of emission peaks are especially at least two emission peaks having different spectral intensity. The emission peaks are each shifted to shorter wavelengths compared to conventional red luminophores, such as SrLiAl₃N₄:Eu²⁺. The luminophore is suitable for use in combination with one or more further luminophores in a radiation-emitting component for generation of a white light with high color rendering. The further luminophores here are selected such that they emit green, yellow and/or orange light after excitation with primary radiation. Thus, a high color rendering index R₉ is achieved. The color rendering index R₉ is a specific color rendering index for saturated red light. Thus, the luminophore described here, when used in radiation-emitting components, compared to the comparative luminophore when used in radiation-emitting components at the same color locus, has an efficiency gain and simultaneously improved color rendering.

The emission spectrum is the distribution of the electromagnetic radiation emitted by the luminophore. Typically, the emission spectrum is represented in the form of a diagram in which a spectral intensity or a spectral radiant flux per wavelength interval (“spectral intensity/spectral radiant flux”) of the electromagnetic radiation emitted by the luminophore or another radiation-emitting element is represented as a function of wavelength λ. In other words, the emission spectrum is a curve in which wavelength is plotted on the x axis, and spectral intensity or spectral radiant flux on the y axis.

In at least one embodiment of the luminophore, a half-height width of an emission peak is between 2 nanometers and 20 nanometers inclusive. In particular, a half-height width of an emission peak is between 3 nanometers and 11 nanometers inclusive. The excitation spectrum here is in the near ultraviolet to blue spectral region, for example with an excitation maximum of about 490 nanometers. In particular, the half height width of each emission peak is between 3 nanometers and 11 nanometers inclusive. The narrowband-emitting luminophore produces comparatively few photons in the deep red spectral region that are perceived only inefficiently by the human eye, while the red color impression of the light and light yield are simultaneously increased.

In at least one embodiment, an emission maximum of an emission peak of the luminophore is between 624 nanometers and 635 nanometers inclusive. The emission maximum is the wavelength λₘₐₓ at which the emission curve of the luminophore attains its maximum value. More particularly, the emission maximum of the luminophore, after excitation with primary radiation in the blue spectral region, is between 625 nm and 634 nm inclusive. Thus, the emission maximum of the luminophore after excitation with primary radiation in the blue spectral region is in the red spectral region. For example, the emission maximum of the luminophores CaZrF₆:Mn and CaHfF₆:Mn is at a wavelength at about 628.3 nm. For example, the emission maximum of the luminophore SrTiF₆:Mn is at a wavelength at about 628.4 nm. For example, the emission maximum of the luminophore ZnHfF₆:Mn is at a wavelength at about 632.7 nm. For example, the emission maximum of the luminophore CaGeF₆:Mn is at a wavelength at about 628.6 nm. For example, the emission maximum of the luminophore CaPbF₆:Mn is at a wavelength at about 629.1 nm. For example, the emission maximum of the luminophore SrSnF₆:Mn is at a wavelength at about 626.6 nm. For example, the emission maximum of the luminophore BaPbF₆:Mn is at a wavelength at about 632.5 nm. For example, the emission maximum of the luminophore ZnSnF₆:Mn is at a wavelength at about 632.6 nm. For example, the emission maximum of the luminophore mgGeF₆:Mn is at a wavelength at about 632.0 nm. For example, the emission maximum of the luminophore CdPbF₆:Mn is at a wavelength at about 631.5 nm. For example, the emission maximum of the luminophore ZnPbF₆:Mn is at a wavelength at about 632.8 nm. For example, the emission maximum of the luminophore mgPbF₆:Mn is at a wavelength at about 633.0 nm. For example, the emission maximum of the luminophore CdHfF₆:Mn in at a wavelength at about 627.3 nm. For example, the emission maximum of the luminophore ZnZrF₆:Mn is at a wavelength at about 632.8 nm. For example, the emission maximum of the luminophore CaSnF₆:Mn is at a wavelength at about 628.5 nm.

Advantageously, the emission maximum of CaZrF₆:Mn, CaHfF₆:Mn, SrTiF₆:Mn, CaGeF₆:Mn, CaPbF₆:Mn, SrSnF₆:Mn, CdHfF₆:Mn and CaSnF₆:Mn, by comparison with conventionally used red-emitting luminophores, especially K₂SiF₆:Mn, is shifted to shorter wavelengths. The sensitivity of the human eye to light is relatively low in the red spectral region, and rises nearly exponentially with decreasing wavelength. The effect of this is that the spectral position of the emission of the luminophore has an extremely strong influence on the overall spectral efficiency of a radiation-emitting component. Thus, in this spectral region, even small shifts of otherwise identical emission bands lead to changes in efficiency in the double-digit percent range of the luminophore.

In at least one embodiment of the luminophore, a luminous efficacy of radiation (LER) is greater than 180 lmW⁻¹. For example, the luminous efficacy of radiation of the luminophore is greater than 202.7 lmW⁻¹. The luminous efficacy of radiation is the quotient of the luminous flux of the radiation and its radiant power. The greater the luminous efficacy of radiation, the greater the luminous flux utilizable by the eye at a given power. Thus, the spectral position of emission of the luminophore described here has an extremely strong influence on the overall luminous efficacy of radiation. Even small shifts in the emission maximum of otherwise identical emission bands lead to improvements in efficiency by up to 15%. For example, the spectral efficiency of the luminophore CaZrF₆:Mn is about 222.2 lmW⁻¹. For example, the spectral efficiency of the luminophore CaHfF₆:Mn is about 219.3 lmW⁻¹. For example, the spectral efficiency of the luminophore SrTiF₆:Mn is about 190.7 lmW⁻¹. For example, the spectral efficiency of the luminophore ZnHfF₆:Mn is about 194.9 lmW⁻¹. For example, the spectral efficiency of the luminophore CaPbF₆:Mn is about 213.4 lmW⁻¹. For example, the spectral efficiency of the luminophore SrSnF₆:Mn is about 228.6 lmW⁻¹. For example, the spectral efficiency of the luminophore BaPbF₆:Mn is about 191.4 lmW⁻¹. For example, the spectral efficiency of the luminophore ZnSnF₆:Mn is about 202.3 lmW⁻¹. For example, the spectral efficiency of the luminophore mgGeF₆:Mn is about 185.6 lmW⁻¹. For example, the spectral efficiency of the luminophore CdPbF₆:Mn is about 206.8 lmW⁻¹. For example, the spectral efficiency of the luminophore ZnPbF₆:Mn is about 181 lmW⁻¹. For example, the spectral efficiency of the luminophore mgPbF₆:Mn is about 205.2 lmW⁻¹. For example, the spectral efficiency of the luminophore CdHfF₆:Mn is about 256.8 lmW⁻¹. For example, the spectral efficiency of the luminophore ZnZrF₆:Mn is about 195.1 lmW⁻¹. For example, the spectral efficiency of the luminophore CaSnF₆:Mn is about 229.9 lmW⁻¹.

In at least one embodiment of the luminophore, a dominant wavelength (λ_{D}) is between 597 nanometers and 621 nanometers inclusive. The dominant wavelength is the wavelength of monochromatic light that creates a similar perception of shade to the polychromatic light mixture to be described. In general, the dominant wavelength differs from the emission maximum. For example, the dominant wavelength of the luminophore CaZrF₆:Mn is at a wavelength AD at about 615.4 nm. For example, the dominant wavelength of the luminophore CaHfF₆:Mn is at a wavelength AD at about 617.2 nm. For example, the dominant wavelength of the luminophore SrTiF₆:Mn is at a wavelength AD at about 612.7 nm. For example, the dominant wavelength of the luminophore ZnHfF₆:Mn is at a wavelength λ_{D} at about 617.7 nm. The dominant wavelength of further working examples of the luminophore can be found in tables 2b, 2c and 2d.

The shape and position of the multitude of emission peaks have an influence on the luminous efficacy of radiation. It is advantageous here that the half height width of the emission peaks has a low width. Thus, comparatively few photons are emitted in the deep red spectral region, which are perceived only very inefficiently by the human eye, while the red color impression of the light is simultaneously retained.

In at least one embodiment, a color locus of the radiation emitted by the luminophore is at a CIE x value between 0.61 and 0.71 exclusive, and at a CIE y value between 0.29 and 0.39 inclusive, in the xy CIE standard color system at an excitation wavelength of 490 nm. The color locus of the luminophore CaZrF₆:Mn is, for example, at CIE x 0.681 and CIE y 0.319. The color locus of the luminophore CaHfF₆:Mn is, for example, at CIE x 0.685 and CIE y 0.315. The color locus of the luminophore SrTiF₆:Mn is, for example, at CIE x 0.674 and CIE y 0.326. The color locus of the luminophore ZnHfF₆:Mn is, for example, at CIE x 0.687 and CIE y 0.313. The color loci of further working examples of the luminophore can be found in tables 2b, 2c and 2d.

Also specified is a process for producing a luminophore. Preference is given to using the process described here to produce the luminophore according to the embodiment cited above. More particularly, all the remarks made in relation to the luminophore are also applicable to the process, and vice versa.

In one embodiment of the process for producing a luminophore having the general formula A_{z}EₑX₆:RE,
A is selected from the group of divalent elements,
E is selected from the group of tetravalent elements,
X is selected from the group of monovalent elements,
RE is selected from activator elements,
0.9≤z≤1.1 and
0.9≤e≤1.1,
   the process comprises the steps of
providing a stoichiometric composition of reactants,
homogenizing the reactants to produce a reaction mixture,
heating the reaction mixture to a maximum temperature.

In at least one embodiment, the reactants are selected from the group comprising halides, carbonates, sulfides, oxides, oxalates, imides, permanganates, nitrates, nitrites, sulfates, sulfites, hydrogensulfates, disulfates, thiosulfates, cyanides, cyanates, thiocyanates, acetates, carboxylic acid derivatives, ternary compounds, especially ammonium compounds, and amides, each of or with A, E, X and RE, and combinations thereof. Preferably, the reactants are selected from a group comprising halides, carbonates, sulfides, oxides, oxalates, imides and amides, each of or with A, E, X and RE, and combinations thereof.

In at least one embodiment, the reactants are selected from a group comprising AX₂, EO₂, ES₂, EOX₂, ACO₃, A(MnO₄)₂ and REX₂ and combinations thereof. Alternatively or additionally, it is possible to obtain the oxides, halides, sulfides and carbonates from organic precursor compounds that form the reactants in situ. For example, it is possible to obtain the oxides via the decarboxylation of oxalates or from carbonates.

In at least one embodiment, the reactants are selected from a group comprising calcium fluoride, hafnium(IV) oxide, manganese(II) chloride tetrahydrate, zinc chloride, strontium carbonate, titanium(IV) sulfide, zirconyl chloride octahydrate, germanium(IV) oxide, lead(II) chloride, tin(II) chloride dihydrate, barium fluoride, zinc carbonate, magnesium fluoride, cadmium chloride, cadmium fluoride, calcium permanganate tetrahydrate and combinations thereof.

In at least one embodiment, elemental X₂ is used as reactant for component X.

In at least one embodiment, the reaction mixture is heated to a maximum temperature of not more than 1000° C. More particularly, the reaction mixture is heated to a maximum temperature of not more than 650° C. Preference is given to heating the reaction mixture to a maximum temperature of not more than 450° C.

In at least one embodiment, the heating takes place in an F₂ stream. More particularly, in the course of heating, up to 100% by volume of F₂ is passed through the reaction mixture. Alternatively, the stream includes F₂ and an inert gas. Preferably, in the course of heating, up to 10% by volume of F₂ in an inert gas is passed through the reaction mixture. For example, the inert gas is He, Ne, Kr, Ar, Xe, N₂ or SF₆. It is thus possible to ensure oxidizing conditions.

In at least one embodiment of the process, no hydrofluoric acid solution is used. The hazard potential resulting from addition of a hydrofluoric acid solution is accordingly avoided.

In at least one embodiment, the heating is a dry high-temperature method. This means that no additional solvents or acids are added in the course of heating. The hazard potential resulting from addition of an acid, especially a hydrofluoric acid solution, is accordingly avoided.

The conventionally used red-emitting luminophore K₂SiF₆:Mn, by contrast, is synthesized industrially with the aid of an aqueous hydrofluoric acid solution. On account of the toxicity and difficulty of handling hydrofluoric acid, this entails very complex safety precautions. In the case of the luminophore described here, however, synthesis is not possible with the aid of an aqueous solution, especially a hydrofluoric acid solution, since the reactants, for example CaF₂ with a solubility of only 0.015 g/L (at 18° C.), SrF₂ with a solubility of only 0.12 g/L (at 27° C.), MgF₂ with a solubility of only 0.087 g/L (at 18° C.) and BaF₂ with a solubility of only 0.16 g/L (at 18° C.), can barely be dissolved in water, and hence synthesis with an aqueous hydrofluoric acid solution is impossible. In addition, the dry high-temperature process is a simplified synthesis route compared to the processes with hydrofluoric acid.

In at least one embodiment of the process, the reactants are homogenized. The resultant reaction mixture of the reactants can then be introduced into the crucible, for example into a corundum boat, and placed in a furnace, especially a tubular furnace, through which up to 100% by volume of F₂ is being passed.

In at least one embodiment, the process comprises stepwise heating of the reaction mixture. What is meant by stepwise heating is that the reaction mixture is heated to at least one intermediate temperature at least one heating rate, and the reaction mixture is kept at an intermediate temperature with a hold time before the maximum temperature is attained. The intermediate temperature is especially lower than the maximum temperature. More particularly, the stepwise heating has two heating rates that may be the same or different.

The intermediate temperature is, for example, between 50° C. and 400° C. inclusive. The hold time is, for example, between one hour and 30 days inclusive. The heating rate is, for example, between 0.05° C. per minute and 5° C. per minute inclusive.

In at least one embodiment, the heating comprises at least one cooling step. The cooling step is especially effected after a heating rate. In the cooling step, the reaction mixture in the furnace is cooled down to a minimum temperature. The minimum temperature is especially between 20° C. and 50° C. inclusive. After the cooling step, the reaction mixture is preferably blended and then heated again.

For example, in a first process step, the reaction mixture is heated to at least two intermediate temperatures at at least two heating rates and kept at an intermediate temperature in each case for at least two hold times. Subsequently, the reaction mixture is cooled down to a minimum temperature in the furnace. In a mixed process step, the reaction mixture is placed in the furnace again and heated at at least one heating rate to an intermediate temperature or maximum temperature and kept at the intermediate temperature or maximum temperature for at least one hold time. Optionally, the reaction mixture, after being heated to a minimum temperature, may be cooled and mixed and heated again at a heating rate in the furnace. After the last hold time at the maximum temperature, the reaction mixture is cooled down to a minimum temperature in the furnace, and a luminophore is obtained.

For example, the reaction mixture is heated at a first heating rate to a first intermediate temperature between 50° C. and 100° C. inclusive. Subsequently, the reaction mixture is kept constant at this intermediate temperature for a first hold time between one hour and 20 hours inclusive. The heating rate and hold time are repeated until a second heating temperature between 300° C. and 370° C. inclusive is attained. The second intermediate temperature is maintained for a second hold time for between two days and 20 days inclusive. Optionally, the reaction mixture may be heated at a heating rate to a third intermediate temperature of about 400° C. and kept constant for a third hold time for five days to 30 days inclusive. Subsequently, the reaction mixture is cooled down to a minimum temperature of about 30° C. in the furnace, removed from the furnace, mixed and placed back into the furnace. The reaction mixture is heated at a heating rate to a fourth intermediate temperature or to a maximum temperature between 300° C. and 450° C. inclusive and kept at this intermediate temperature or maximum temperature for a fourth hold time of two days to 14 days inclusive. Optionally, the reaction mixture can be heated to a maximum temperature of 450° C. at a fifth heating rate and kept at this maximum temperature for a fifth hold time for one day. It is also possible, after a fourth intermediate temperature, to cool the reaction mixture back down to a minimum temperature and heat it again in the furnace at a heating rate to a maximum temperature of 450° C. This maximum temperature is kept constant for four to 14 days. Subsequently, the reaction mixture is cooled down to a minimum temperature.

In at least one embodiment of the process, a stoichiometric composition of the reactants calcium fluoride, zirconyl chloride octahydrate and manganese(II) chloride tetrahydrate is provided. More particularly, a stoichiometric composition of these reactants is suitable for preparation of a luminophore of the formula CaZrF₆:Mn.

In at least one embodiment of the process, a stoichiometric composition of the reactants calcium fluoride, hafnium(IV) oxide and manganese(II) chloride tetrahydrate is provided. More particularly, a stoichiometric composition of these reactants is suitable for preparation of a luminophore of the formula CaHfF₆:Mn.

In at least one embodiment of the process, a stoichiometric composition of the reactants strontium carbonate, titanium(IV) sulfide and manganese(II) chloride tetrahydrate is provided.

More particularly, a stoichiometric composition of these reactants is suitable for preparation of a luminophore of the formula SrTiF₆:Mn.

In at least one embodiment of the process, a stoichiometric composition of the reactants zinc chloride, hafnium(IV) oxide and manganese(II) chloride tetrahydrate is provided. More particularly, a stoichiometric composition of these reactants is suitable for preparation of a luminophore of the formula ZnHfF₆:Mn.

In at least one embodiment of the process, a stoichiometric composition of the reactants calcium fluoride, germanium(IV) oxide and manganese(II) chloride tetrahydrate is provided. More particularly, a stoichiometric composition of these reactants is suitable for preparation of a luminophore of the formula CaGeF₆:Mn.

In at least one embodiment of the process, a stoichiometric composition of the reactants calcium fluoride, lead(II) chloride and manganese(II) chloride tetrahydrate is provided. More particularly, a stoichiometric composition of these reactants is suitable for preparation of a luminophore of the formula CaPbF₆:Mn.

In at least one embodiment of the process, a stoichiometric composition of the reactants strontium carbonate, tin(II) chloride dihydrate and manganese(II) chloride tetrahydrate is provided. More particularly, a stoichiometric composition of these reactants is suitable for preparation of a luminophore of the formula SrSnF₆:Mn.

In at least one embodiment of the process, a stoichiometric composition of the reactants barium fluoride, lead(II) chloride and manganese(II) chloride tetrahydrate is provided. More particularly, a stoichiometric composition of these reactants is suitable for preparation of a luminophore of the formula BaPbF₆:Mn.

In at least one embodiment of the process, a stoichiometric composition of the reactants zinc carbonate, tin(II) chloride dihydrate and manganese(II) chloride tetrahydrate is provided. More particularly, a stoichiometric composition of these reactants is suitable for preparation of a luminophore of the formula ZnSnF₆:Mn.

In at least one embodiment of the process, a stoichiometric composition of the reactants magnesium fluoride, germanium(IV) oxide and manganese(II) chloride tetrahydrate is provided. More particularly, a stoichiometric composition of these reactants is suitable for preparation of a luminophore of the formula MgGeF₆:Mn.

In at least one embodiment of the process, a stoichiometric composition of the reactants cadmium chloride, lead(II) chloride and manganese(II) chloride tetrahydrate is provided. More particularly, a stoichiometric composition of these reactants is suitable for preparation of a luminophore of the formula CdPbF₆:Mn.

In at least one embodiment of the process, a stoichiometric composition of the reactants zinc carbonate, lead(II) chloride and manganese(II) chloride tetrahydrate is provided. More particularly, a stoichiometric composition of these reactants is suitable for preparation of a luminophore of the formula ZnPbF₆:Mn.

In at least one embodiment of the process, a stoichiometric composition of the reactants magnesium fluoride, lead(II) chloride and manganese(II) chloride tetrahydrate is provided. More particularly, a stoichiometric composition of these reactants is suitable for preparation of a luminophore of the formula MgPbF₆:Mn.

In at least one embodiment of the process, a stoichiometric composition of the reactants cadmium fluoride, manganese fluoride and hafnium(IV) chloride tetrahydrate is provided. More particularly, a stoichiometric composition of these reactants is suitable for preparation of a luminophore of the formula CdHfF₆:Mn.

In at least one embodiment of the process, a stoichiometric composition of the reactants zinc carbonate, zirconyl chloride octahydrate and manganese(II) chloride tetrahydrate is provided. More particularly, a stoichiometric composition of these reactants is suitable for preparation of a luminophore of the formula ZnZrF₆:Mn.

In at least one embodiment of the process, a stoichiometric composition of the reactants calcium fluoride, tin(II) chloride dihydrate and calcium permanganate tetrahydrate is provided. More particularly, a stoichiometric composition of these reactants is suitable for preparation of a luminophore of the formula CaSnF₆:Mn.

Also specified is a radiation-emitting component comprising at least one luminophore. The luminophore according to the abovementioned embodiments is preferably suitable and intended for use in a radiation-emitting component as described here. Features and embodiments that are mentioned solely in connection with the luminophore and/or process are also applicable to the radiation-emitting component, and vice versa.

The radiation-emitting component is a component that emits electromagnetic radiation in operation. For example, the radiation-emitting component is a light-emitting diode (LED).

In at least one embodiment, the radiation-emitting component comprises a semiconductor chip which, in operation, emits electromagnetic radiation in a first wavelength range. The semiconductor chip may comprise an active layer sequence containing an active region which, in operation of the component, can generate the electromagnetic radiation of the first wavelength range, the primary radiation. The semiconductor chip is, for example, a light-emitting diode chip or a laser diode chip. The primary radiation which is generated in the semiconductor chip may be emitted through a radiation exit face of the semiconductor chip. The primary radiation may form a beam path or follow a beam path.

The primary radiation may especially comprise wavelengths in the visible region. For example, the semiconductor chip emits primary radiation in the blue spectral region, especially in the wavelength range from 400 nm or 430 nm to 550 nm inclusive, preferably from 450 nm to 520 nm inclusive, more preferably from 470 nm to 510 nm inclusive.

In at least one embodiment, the radiation-emitting component comprises a conversion element including a luminophore having the general formula A_{z}EₑX₆:RE that converts electromagnetic radiation in the first wavelength range to electromagnetic radiation in a second wavelength range, where
A is selected from the group of divalent elements,
E is selected from the group of tetravalent elements,
X is selected from the group of monovalent elements,
RE is selected from activator elements,
0.9≤z≤1.1 and
0.9≤e≤1.1.

The properties of the luminophore are already disclosed in relation to the luminophore and are likewise applicable to the luminophore in the radiation-emitting component. The luminophore converts the primary radiation completely or at least partly to electromagnetic radiation in a second wavelength range, called the secondary radiation. In particular, the secondary radiation has at least partly different wavelength ranges than the primary radiation.

The conversion element is especially disposed in the beam path of the primary radiation in such a way that at least a portion of the primary radiation hits the conversion element.

In at least one embodiment, the conversion element is applied in direct contact on the radiation exit face of the semiconductor chip.

In at least one embodiment, the conversion element is applied with the aid of an adhesive layer on the radiation exit face.

In at least one embodiment, the semiconductor chip and the conversion element are disposed in the recess of a housing. In a further embodiment, the semiconductor chip and/or the conversion element or at least partly surrounded by an encapsulant.

In at least one embodiment, the semiconductor chip and the conversion element are disposed in the recess of a housing, with the recess of the housing filled with an encapsulant that at least partly surrounds the semiconductor chip, and the conversion element being disposed on the side of the encapsulant remote from the semiconductor chip.

In at least one embodiment, the semiconductor chip is disposed in the recess of a housing, with the recess of the housing filled with an encapsulant that at least partly surrounds the semiconductor chip, and the conversion element disposed on the side of the encapsulant remote from the semiconductor chip outside the recess of the housing. It is optionally possible for particles, for example luminophores for scattering particles, to be embedded within the encapsulant.

In at least one embodiment, the conversion element is part of an encapsulant of the radiation-emitting component, for the conversion element forms the encapsulant. The semiconductor chip is especially embedded into the conversion element and at least partly surrounded by the conversion element. In at least one embodiment, the encapsulant is disposed in the recess of the housing.

In at least one embodiment, the recess of the housing between the semiconductor chip and the conversion element is free of any encapsulant and/or further layers or components.

In at least one embodiment, the encapsulant has a transparency to electromagnetic radiation, especially the primary radiation, of at least 85%, especially of at least 95%.

In at least one embodiment, the encapsulant comprises glass such as silicate, waterglass or quartz glass, or polymers such as polystyrene, polysiloxane, polysilazane, PMMA, polycarbonate, polyacrylate, polytetrafluoroethylene, polyvinyl, silicone resin, silicone or epoxy resin or combinations thereof.

Such a radiation-emitting component can especially generate narrowband radiation in the red wavelength range after excitation with primary radiation. In combination with one or more further luminophores, the radiation-emitting component may thus preferably be used for generation of cold white, warm white or—in the case of full conversion—red light, for example in display applications.

In at least one embodiment, the conversion element converts the primary radiation partly to secondary radiation, with the unconverted portion of the primary radiation being transmitted by the conversion element. In other words, partial conversion of the primary radiation to secondary radiation takes place. The radiation-emitting component in this case emits mixed light composed of the primary radiation and secondary radiation. For example, the radiation-emitting component emits light composed of primary radiation in the blue spectral region and secondary radiation in the red spectral region. More particularly, combination with one or more further luminophores can generate white light with a high color rendering index Rₐ and a low color temperature.

In at least one embodiment, no primary radiation is transmitted by the conversion element. What is meant by “no” in this context is that so little primary radiation is transmitted that it no longer perceptibly affects the light emitted by the component. For example, not more than 10%, especially not more than 5% and preferably not more than 1% of the primary radiation is transmitted by the conversion element. In that case, the radiation-emitting component emits merely the secondary radiation. In other words, for conversion of the primary radiation to secondary radiation takes place. Thus, the conversion element converts the primary radiation outwardly virtually completely to secondary radiation. For example, the radiation-emitting component emits red light without a blue component. By comparison with commercial red luminophores having a similar dominant wavelength, especially K₂SiF₆:Mn⁴⁺, working examples of the present luminophore, on account of its narrowband emission at shorter wavelengths in the red region, have a distinctly superior luminous efficiency in the red region.

In at least one embodiment, the conversion element is free of a further luminophore. What is meant by “free of a further luminophore” is that only one luminophore covered by the formula of the luminophore A_{z}EₑX₆:RE or a mixture of different luminophores covered by the formula of the luminophore A_{z}EₑX₆:RE are present in the conversion element of the radiation-emitting component for wavelength conversion and lead to a wavelength conversion within the radiation-emitting component.

In at least one embodiment, the conversion element comprises a second luminophore that converts electromagnetic radiation in a first wavelength range to electromagnetic radiation in a third wavelength range. The third wavelength range is different than the first and the second wavelength range.

In at least one embodiment, the second luminophore is a yellow-emitting luminophore that converts the primary radiation to a yellow secondary radiation. In particular, the second luminophore absorb some converts blue primary radiation, especially having a wavelength range from 430 nm to 550 nm inclusive, preferably from 450 nm to 520 nm inclusive.

Yellow-emitting luminophores used may especially be garnet luminophores, for example (Lu,Y,Gd,Tb)₃(Al,Ga)₅O₁₂:Ce, orthosilicates, for example (Ca,Ba,Sr)₂SiO₄:Eu²⁺, or nitrides such as La₃Si₆N₁₁:Ce³⁺. The luminophore (Lu,Y,Gd,Tb)₃(Al,Ga)₅O₁₂:Ce has at least one of the elements Lu, Y, Gd and Tb and at least one of the elements Al and Ga. The luminophore (Ca,Ba,Sr)₂SiO₄:Eu²⁺ has at least one of the elements Ca, Ba and Sr.

In at least one embodiment, the second luminophore is a green-emitting luminophore that converts the primary radiation to a green secondary radiation. More particularly, the second luminophore absorbs and converts blue primary radiation, especially having a wavelength range from 530 nm to 590 nm inclusive, preferably from 550 nm to 590 nm inclusive.

The green-emitting luminophore used may especially be the garnet luminophore (Lu,Y,Gd,Tb)₃(Al,Ga)₅O₁₂:Ce.

Use of a second luminophore in combination with a luminophore of the general formula A_{z}EₑX₆:RE allows the color locus of the radiation-emitting component to be adjusted.

When a second luminophore is used in combination with a luminophore of the general formula AₐEₑX₆:RE in the radiation-emitting component, it is possible to generate a mixed light having a color locus in the warm white region. More particularly, the mixed light with a color locus in the warm white region is generated by a combination of the blue primary radiation from the semiconductor chip, the red secondary radiation from the luminophore described here, and the yellow or green secondary radiation from the yellow- or green-emitting second luminophore. It is thus possible to generate warm white mixed light having a high color rendering index Rₐ, for example about 92, and a color temperature between 2600 K and 3200 K inclusive, especially 2993 K and 3008 K inclusive.

In at least one embodiment, the conversion element comprises at least two differently emitting luminophores. The conversion element includes, for example, the present luminophore, a green-emitting luminophore and a yellow-emitting luminophore.

By comparison with a radiation-emitting component with the conventionally used red-emitting luminophore K₂SiF₆:Mn in combination with the same blue-emitting semiconductor chip and the same second luminophore, the radiation-emitting component described here can lead to a higher luminous efficacy of radiation LER by at least 2%.

In addition, a high red color rendering index R₉ is achieved. The red color rendering index R₉ is a specific color rendering index for saturated red colors.

Thus, the radiation-emitting component described here, by comparison with the conventional radiation-emitting component, with the same color locus, has an efficiency gain and simultaneously improved color rendering.

In at least one embodiment, the luminophore in the conversion element is in the form of a ceramic or in a matrix material. A luminophore in the form of a ceramic is especially very substantially free of any matrix material and/or any further luminophore. The ceramic formed from the luminophore preferably has a low porosity. It is thus possible to prevent or virtually prevent unwanted light scatter, and there is good removal of heat.

Alternatively, the luminophore, especially in particle form, is embedded in a matrix material. The matrix material comprises, for example, the abovementioned materials for encapsulation. More particularly, the surface of the luminophore may be passivated for embedding into a matrix material. It is possible for more than one luminophore to be embedded in a matrix material. For example, particles of two luminophores are embedded in the matrix material.

### BRIEF DESCRIPTION OF THE DRAWINGS

Further advantageous embodiments, configurations and developments of the luminophore, of the process for producing a luminophore and of the radiation-emitting component will be apparent from the working examples that follow, which are described in conjunction with the figures.

FIGS. 1, 2 and 31 show details from various viewing directions of the host lattice of the luminophore, each in one working example,

FIGS. 3, 5, 7 and 8 show powder diffractograms of the luminophore, each in one working example,

FIGS. 4, 6, 9, 27, 28, 29, 30, 35, 38 and 39 show Rietveld-refined powder diffractograms, each in one working example,

FIGS. 10, 11 and 12 show excitation spectrum of the luminophore, each in one working example,

FIGS. 13, 15, 17, 18, 40, 41, 42, 43, 44, 45, 46, 47, 48, 49, 50 and 51 show emission spectrum of luminophore, each in one working example,

FIGS. 14 and 16 show emission spectrum of the luminophore, each in one working example and one comparative example,

FIGS. 19 and 20 show a comparison of the relative luminous efficacy of radiation of the luminophore, each in one working example and one comparative example,

FIG. 21 shows a schematic section diagram for various process stages of a process for producing a luminophore in one working example,

FIGS. 22, 23 and 24 show a radiation-emitting component in schematic section view, each in one working example,

FIGS. 25 and 26 show simulated LED emission spectrum with the luminophore, each in one working example, and with one comparative example, and

FIGS. 32, 33, 34, 36 and 37 show Le Bail-refined powder diffractograms, each in one working example.

Elements that are the same, of the same type will have the same effect are given the same reference numerals in the figures. The figures and size ratios of the elements shown in the figures with respect to one another should not be considered to be true to scale. Instead, individual elements, especially layer thicknesses, may be shown in excessively large size for better illustratability and/or the better understanding.

### DETAILED DESCRIPTION

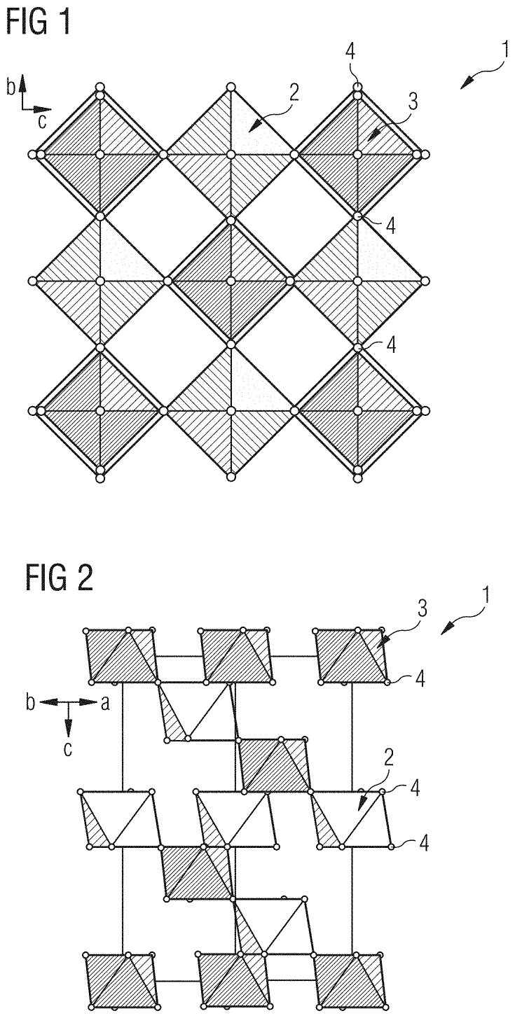

FIG. 1 shows a detail of the host lattice of the luminophore 1 A_{z}EₑX₆:RE according to the working examples CaZrF₆:Mn, CaHfF₆:Mn, CaPbF₆:Mn, SrSnF₆:Mn, CdHfF₆:Mn, ZnZrF₆:Mn and CaSnF₆:Mn in a schematic diagram. The host lattice has a structure with a cubic Fm3̅m space group. The structure of the host lattice has vertex-linked AX₆ octahedra 2 and EX₆ octahedra 3. In the present case, the host lattice has AX₆ octahedra 2 with A=Ca, Sr, Cd or Zn and X=F, i.e. CaF₆ octahedra, SrF₆ octahedra, CdF₆ octahedra or ZnF₆ octahedra, and EX₆ octahedra 3 with E=Zr, Hf, Pb or Sn, i.e. ZrF₆ octahedra, HfF₆ octahedra, PbF₆ octahedra or SnF₆ octahedra.

What is meant here and hereinafter by “vertex-linked” is that two octahedra are joined to one another via a common vertex 4. The vertex 4 in the present case is a common F atom. FIG. 1 extends in the be plane and thus has a viewing direction in [100] direction. The structures of the working examples CaZrF₆:Mn, CaHfF₆:Mn, CaPbF₆:Mn, SrSnF₆:Mn, CdHfF₆:Mn, ZnZrF₆:Mn and CaSnF₆:Mn were ascertained by x-ray structure analysis measurements.

The AF₆ octahedron and the EF₆ octahedron each have an octahedral vacancy. The octahedral vacancy is a region within the respective octahedron. The fluorine atoms form the octahedron, with the A atom and E atom present in the octahedral vacancy of the octahedron formed by the fluorine atoms. In this case, preferably all atoms that form the octahedron at a similar distance from the A atom and the E atom present in the octahedral gap.

At least one AF₆ octahedron and one EF₆ octahedron are links to one another via a fluorine atom. The fluorine atom that links the AF₆ octahedron and the EF₆ octahedron is a common fluorine atom.

FIG. 2, by comparison with FIG. 1, has a viewing direction in the [110] direction. What is shown is a detail of the host lattice of the luminophore 1 A_{z}EₑX₆:RE according to the working example CaZrF₆:Mn, CaHfF₆:Mn, CaPbF₆:Mn, SrSnF₆:Mn, CdHfF₆:Mn, ZnZrF₆:Mn and CaSnF₆:Mn in a schematic diagram. The most lattice has a structure with a trigonal R3̅ space group. In the present case, the host lattice of ZnHfF₆:Mn, CaGeF₆:Mn, ZnSnF₆:Mn, MgGeF₆:Mn, CdPbF₆:Mn, ZnPbF₆:Mn and mgPbF₆:Mn has AX₆ octahedra 2 with A=Ca, Mg or Zn and X=F, i.e. CaF₆ octahedra, MgF₆ octahedra or ZnF₆ octahedra, and EX₆ octahedra with E=Hf, Ge, Pb or Sn, i.e. HfF₆ octahedra, GeF₆ octahedra, PbF₆ octahedra or SnF₆ octahedra. The host lattice of CdPbF₆:Mn has AX₆ octahedra 2 and 3 with A=Cd and X=F, and EX₆ octahedra 2 and 3 with E=Pb and X=F. In the case of CdPbF₆:Mn, the octahedra 2 and 3 are consequently CdF₆ octahedra and PbF₆ octahedra respectively. Here too, the octahedra are linked via common fluorine atoms.

In FIGS. 1 and 2, for clarity, not all octahedra and atoms are given a reference numeral.

Table 1 below shows the crystallographic data of the working examples CaZrF₆:Mn, CaHfF₆:Mn and ZnHfF₆:Mn, CaGeF₆:Mn, CaPbF₆:Mn, SrSnF₆:Mn, BaPbF₆:Mn, ZnSnF₆:Mn, MgGeF₆:Mn, CdPbF₆:Mn, ZnPbF₆:Mn, MgPbF₆:Mn, CdHfF₆:Mn, CaSnF₆:Mn, ZnZrF₆:Mn of the luminophores 1. The crystallographic data were obtained from a Rietveld refinement or Le Bail refinement, as described in detail in relation to FIGS. 4, 6, 9, 27, 28, 29, 30, 32, 33, 34, 35, 36, 37, 38 and 39. What are described are firstly the lattice parameters a and c, the unit cell volume V of the unit cell, and secondly the space group.

TABLE 1
Crystallographic data of CaZrF₆: Mn, CaHfF₆: Mn,
ZnHfF₆: Mn, CaGeF₆: Mn, CaPbF₆: Mn, SrSnF₆: Mn,
BaPbF₆: Mn, ZnSnF₆: Mn, MgGeF₆: Mn, CdPbF₆:
Mn, ZnPbF₆: Mn, MgPbF₆: Mn, CdHfF₆: Mn,
CaSnF₆: Mn and ZnZrF₆: Mn.

| Lumino- | | | | Space |
|---|---|---|---|---|
| phore | a/Å | c/Å | V/Å³ | group |
| CaZrF₆: Mn | 8.477 | — | 609.2 | Fm3̅m |
| | (1) | | (1) | |
| CaHfF₆: Mn | 8.473 | — | 608.3 | Fm3̅m |
| | (5) | | (4) | |
| ZnHfF₆: Mn | 5.58 | 13.79 | 372.1 | R3̅ |
| | (1) | (2) | (8) | |
| CaGeF₆: Mn | 5.4507 | 13.972 | 359.50 | R3̅ |
| | (10) | (3) | (13) | |
| CaPbF₆: Mn | 8.48789 | — | 611.50 | Fm3̅m |
| | (19) | | (2) | |
| SrSnF₆: Mn | 8.6292 | | 642.6 | Fm3̅m |
| | (18) | | (2) | |
| BaPbF₆: Mn | 7.46808 | 7.52926 | 363.664 | R3̅m |
| | (12) | (15) | (11) | |
| ZnSnF₆: Mn | 5.2239 | 13.845 | 327.20 | R3̅ |
| | (9) | (2) | (8) | |
| MgGeF₆: Mn | 5.076 | 13.080 | 291.9 | R3̅ |
| | (3) | (10) | (2) | |
| CdPbF₆: Mn | 5.3741 | 15.094 | 377.53 | R3̅ |
| | (6) | (2) | (6) | |
| ZnPbF₆: Mn | 5.21055 | 14.2174 | 344.285 | R3̅ |
| | (10) | (3) | (12) | |
| MgPbF₆: Mn | 5.2683 | 13.967 | 335.71 | R3̅ |
| | (8) | (3) | (9) | |
| CdHfF₆: Mn | 8.348 | | 581.80 | Fm3̅m |
| | (2) | | (11) | |
| ZnZrF₆: Mn | 7.972 | | 506.6 | Fm3̅m |
| | (3) | | (3) | |
| CaSnF₆: Mn | 8.3441 | | 580.95 | Fm3̅m |
| | (2) | | (2) | |

The composition of the luminophore 1 according to the working example SrTiF₆:Mn was confirmed by means of elemental analysis (MP-AES, microwave plasma atomic emission spectroscopy). The actual value for Sr is 37.0% by mass and the actual value for Ti in the luminophore SrTiF₆:Mn is 17.8% by mass. The theoretical value for Sr is 35.0% by mass and the theoretical value for Ti is 18.2% by mass. The variances between measured actual values and calculated theoretical values are within the standard experimental error limits for the analysis method used.

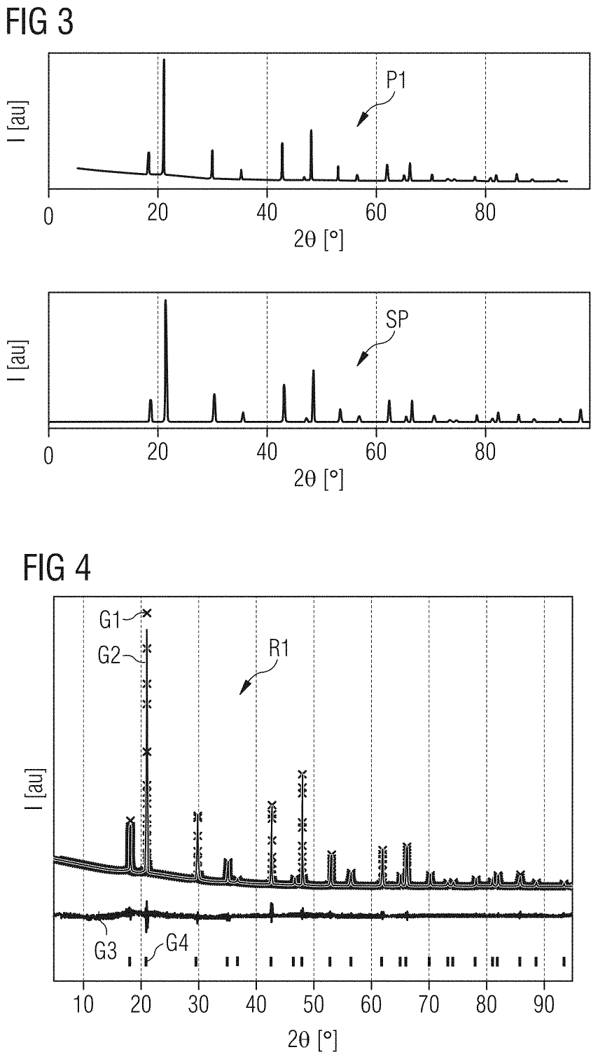

FIGS. 3, 5, 7 and 8 show, by way of example, the powder diffractograms of different working examples of the luminophore 1 measured using copper-Kai radiation with a wavelength of 154.06 pm. Relative intensity I is plotted here in arbitrary units, in each case against the diffraction angle 20 in degrees between a radiation source of the x-radiation, the luminophore 1 and a detector for the x-radiation.

FIG. 3 shows the powder diffractogram P1 of the luminophore 1 of the working example CaZrF₆:Mn. FIG. 3 also shows, in the section of the powder diffractogram SP, the comparative diffractogram calculated from literature data for undoped CaZrF₆. Clear agreement of the two powder diffractograms is apparent, which is attributable to phase purity of the luminophore 1 having the formula CaZrF₆:Mn. CaZrF₆ and a luminophore 1 according to the working example CaZrF₆:Mn crystallize in the same crystal structure. The phase purity and crystal structure of the luminophore 1 according to the working example CaZrF₆:Mn were thus determined by means of x-ray powder diffractometry.

FIGS. 4, 6, 9, 27, 28, 29, 30, 35, 38 and 39 each show Rietveld-refined powder diffractograms of various working examples of the luminophore 1. Relative intensity I is likewise plotted here in arbitrary units against the diffraction angle 2θ. The crosses shown in the powder diffractogram are the measured reflections G1 of the working example of the luminophore 1. G3 describes a difference diagram G3, and G2 describes a calculated powder diffractogram G2. The black marks G4 show the calculated reflection positions of the luminophore. G5 and G6 show the calculated reflection positions of any secondary crystalline phases.

FIG. 4 shows a Rietveld-refined powder diffractogram are one of the luminophore 1 according to the working example CaZrF₆:Mn. Here too, good agreement of the calculated powder diffractogram G2 with the measure diffractogram G1 is apparent. Aside from the luminophore having the formula CaZrF₆:Mn, there are no secondary crystalline phases. It is thus possible to verify the crystal structure of the working example CaZrF₆:Mn.

FIG. 5, analogously to FIG. 3, shows a measured powder diffractogram P2 of the luminophore, here according to working example CaHfF₆:Mn. The crystal structure of the working example CaHfF₆:Mn can be determined therefrom.

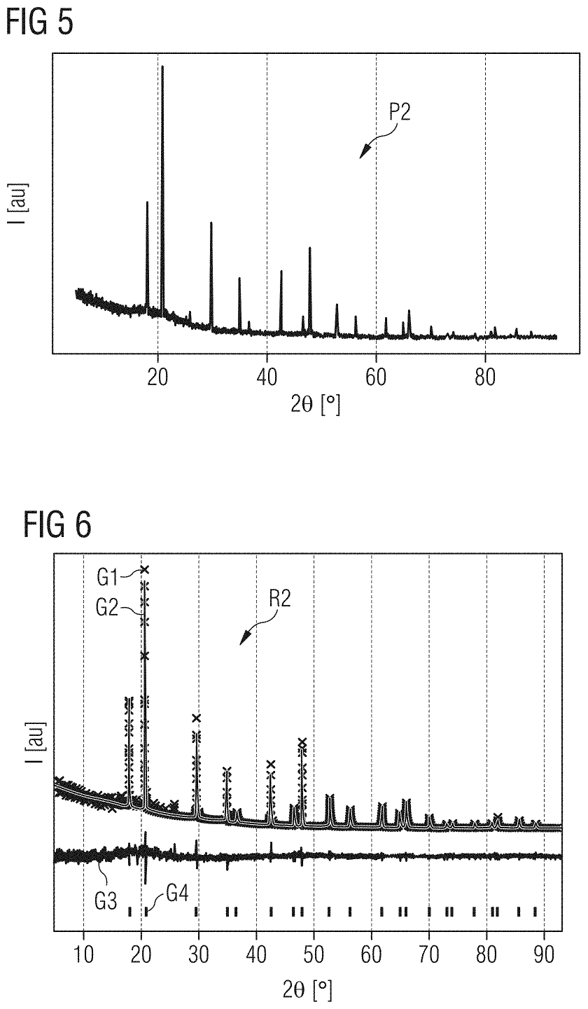

FIG. 6, analogously to FIG. 4, shows a Rietveld-refined powder diffractogram R2 of the luminophore 1, according to the working example CaHfF₆:Mn. The crystal structure CaHfF₆ was confirmed as being isotypic with CaZrF₆ by means of the Rietveld refinement of the measured x-ray powder data. For this purpose, proceeding from the crystal structure of CaZrF₆, a structure model was created, in which Zr is replaced by Hf, and which was subsequently refined.

Aside from the luminophore 1 having the formula CaHfF₆:Mn, no secondary crystalline phases are present. Here too, good agreement of the calculated powder diffractogram G2 with the measure diffractogram G1 is apparent. It was thus confirmed that CaZrF₆:Mn and CaHfF₆:Mn are isotypic with one another. What is meant by the term “isotypic” is that the compounds have the same crystal structure. Thus, the working examples CaZrF₆:Mn and CaHfF₆:Mn of the luminophore 1 have the same crystal structure.

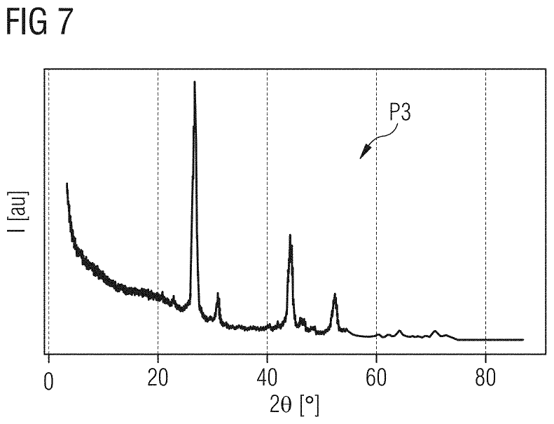

FIG. 7, analogously to FIGS. 3 and 5, shows a measured powder diffractogram P3 of the luminophore 1 according to the working example SrTiF₆:Mn. The reflection positions agree with already known reflection positions.

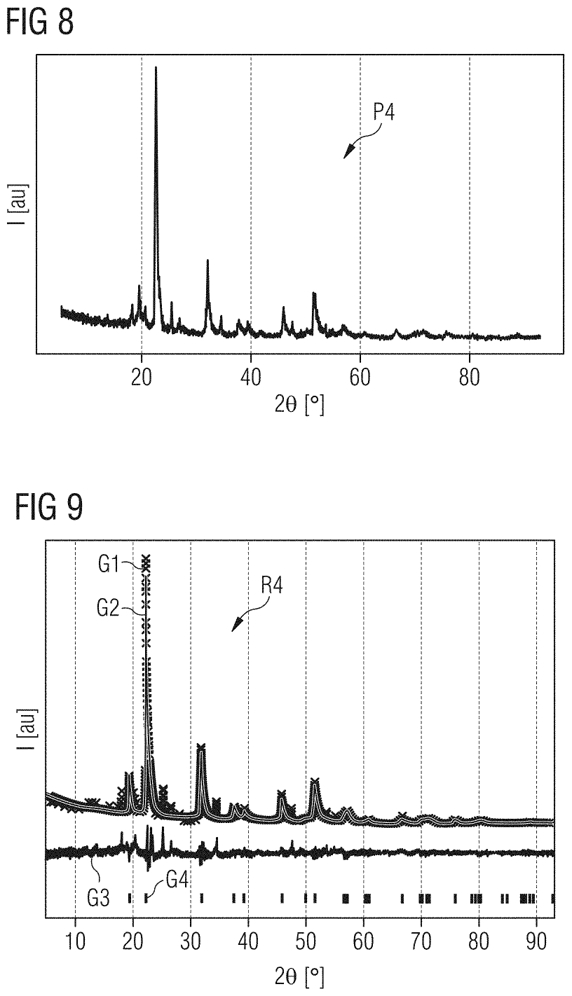

FIG. 8 shows a powder diffractogram P4 of the luminophore 1 according to the working example ZnHfF₆:Mn.

By subsequent Rietveld refinement, shown in FIG. 9, the phase composition of the luminophore 1 according to the working example ZnHfF₆:Mn was determined. The Rietveld-refined powder diffractogram R4 shows that ZnHfF₆:Mn is isotypic with the compound LiSbF₆. Proceeding from the compound LiSbF₆, a crystal structure model was created for ZnHfF₆, in which Li was replaced by Zn and Sb by Hf. It is apparent in FIG. 9 that, except for a few comparatively weak reflections of HfF₄ and ZnF₂, the experimental powder diffractogram can be well explained by the structure model for ZnHfF₆.

FIGS. 10, 11 and 12 each show an excitation spectrum of working examples of the luminophore 1. Intensity I here is plotted here in arbitrary units against wavelength λ in nm. The intensity I of the spectral line was measured here at 628 nm, and the excitation wavelength was tuned continuously. The luminophore 1 shows two excitation bands. One excitation band of the luminophore 1 is in the near-UV region between 320 nm and 420 nm inclusive, and the second excitation band is in the blue spectral region between 430 nm and 550 nm inclusive. The excitation maxima of the two excitation bands are at about 370 nm and at about 490 nm. Thus, the luminophore 1 finds use in radiation-emitting components with blue primary radiation.

FIG. 10 shows an excitation spectrum A1 of the luminophore 1 according to the working example CaZrF₆:Mn.

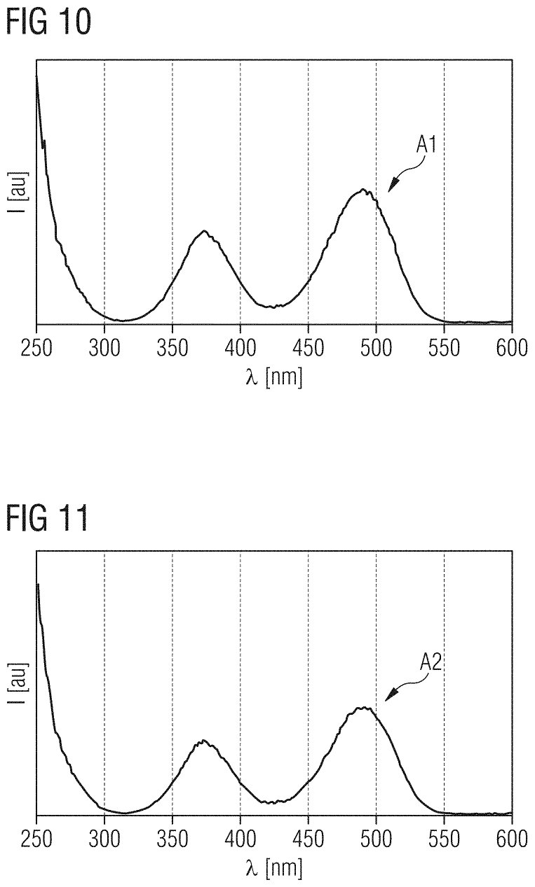

FIG. 11 shows an excitation spectrum A2 of the luminophore 1 according to the working example CaHfF₆:Mn.

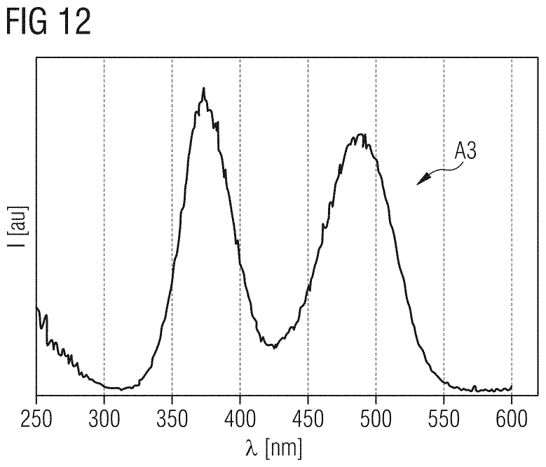

FIG. 12 shows an excitation spectrum A3 of the luminophore 1 according to the working example SrTiF₆:Mn.

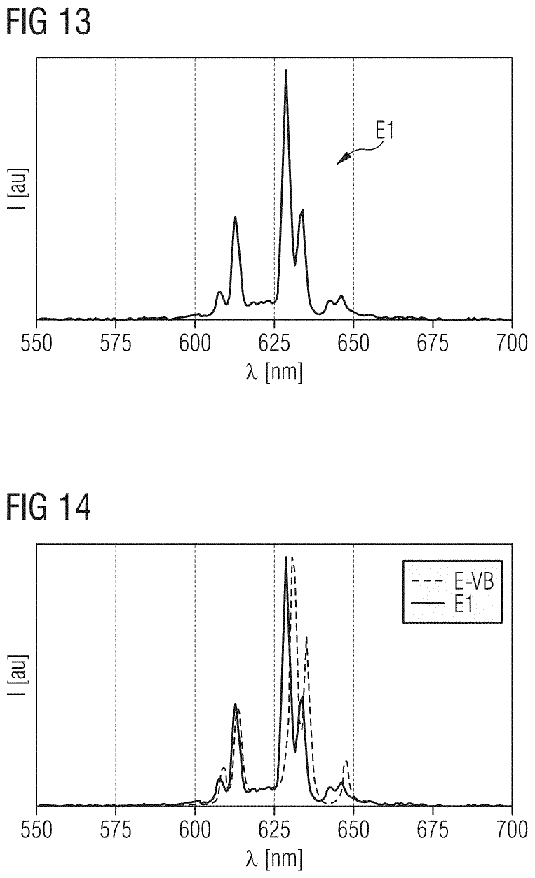

FIGS. 13 to 18 and 40 to 51 each show emission spectra of various working examples of the luminophore 1 with characteristic Mn⁴⁺ line emissions. The respective luminophore 1 was excited with blue primary radiation having a wavelength of 490 nm in the case of luminophore 1 of the working examples CaZrF₆:Mn, CaHfF₆:Mn, CaPgF₆:Mn and SrTiF₆:Mn, or of 500 nm in the case of luminophore 1 of the working examples ZnHfF₆:Mn, ZnSnF₆:Mn and ZnZrF₆:Mn, or 470 nm in the case of luminophore 1 of the working examples CaGeF₆:Mn, CaPbF₆:Mn, SrSnF₆:Mn, BaPbF₆:Mn, CdHfF₆:Mn, or of 480 nm in the case of luminophore 1 of the working examples mgGeF₆:Mn, ZnPbF₆:Mn, CaSnF₆:Mn and mgPbF₆:Mn. What is plotted is the relative intensity I in arbitrary units against the wavelength λ in nm. The emission spectra show a multitude of emission peaks between 600 nm and 700 nm, with a half-height width of an emission peak between 2 nanometers and 20 nanometers inclusive.

FIG. 13 shows an emission spectrum E1 of the working example CaZrF₆:Mn of the luminophore 1. The emission peak having the highest intensity has an emission maximum λₘₐₓ of 628.3 nm. A dominant wavelength λ_{D} is 615.4 nm.

FIG. 14 shows the emission spectra of the luminophore 1 according to the working example CaZrF₆:Mn (E1) and a comparative example (E-VB), a commercial fluoride luminophore of the K₂SiF₆:Mn type. The comparative example E-VB likewise emits in the red spectral region and has a comparable color impression, measured by the dominant wavelength λ_{D}. However, it is clearly apparent that the emission spectrum E1 of the luminophore according to working example CaZrF₆:Mn, by comparison with the emission spectrum of the comparative example E-VB, has been shifted to shorter wavelengths by about 2 nm, and hence toward the region of better eye sensitivity. This leads to improved spectral efficiency and a gain of almost 10% in luminous efficacy of radiation (LER) compared to the comparative example. Table 2a below compares the optical properties of the luminophore 1 according to the working example CaZrF₆:Mn and the comparative example.

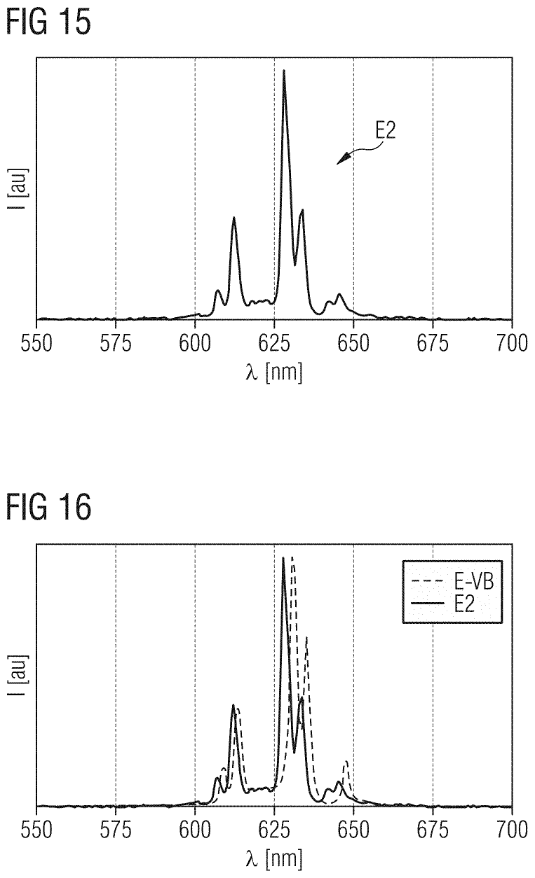

FIG. 15 shows an emission spectrum E2 of the luminophore 1 according to the working example CaHfF₆:Mn. The emission peak having the highest intensity has an emission maximum Amax of 628.3 nm. A dominant wavelength λ_{D} is 617.2 nm.

FIG. 16 shows the emission spectra of the luminophore 1 according to the working example CaHfF₆:Mn (E2) and of the comparative example (E-VB), a commercial fluoride luminophore of the K₂SiF₆:Mn type. It is clearly apparent that the emission spectrum E2 of the working example CaHfF₆:Mn here too, by comparison with the emission spectrum of the comparative example E-VB, has been shifted by about 2 nm to shorter wavelengths, and hence toward the region of better eye sensitivity. This leads to improved spectral efficiency and to a gain of almost 10% in luminous efficacy radiation (LER) compared to the comparative example E-VB. Table 2a below compares the optical properties of the luminophore 1 having the formula CaHfF₆:Mn and of the comparative example.

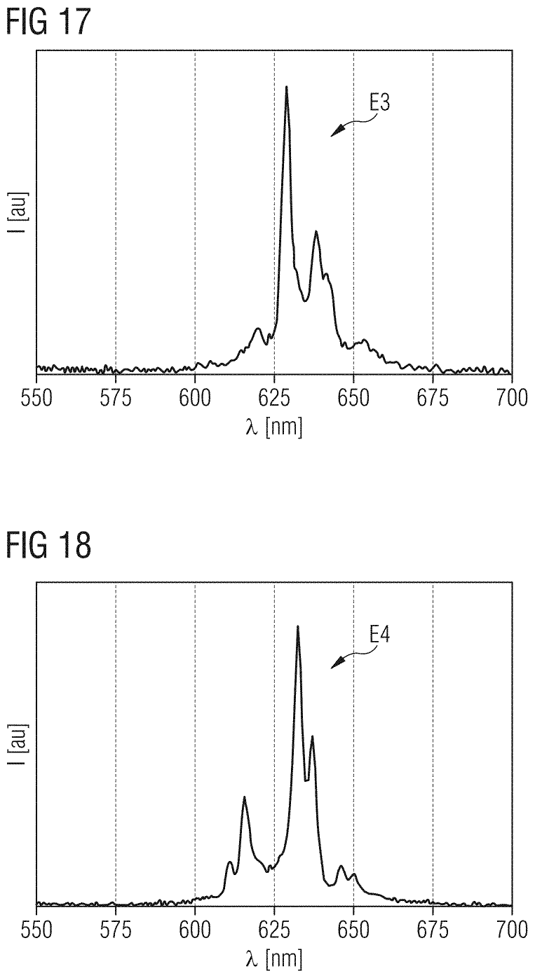

FIG. 17 shows an emission peak E3 of the luminophore 1 according to the working example SrTiF₆:Mn. The emission peak having the highest intensity here too has an emission maximum Amax of 628.4 nm. A dominant wavelength λ_{D} is 612.7 nm.

FIG. 18 shows an emission peak E4 of the luminophore 1 according to the working example ZnHfF₆:Mn. The emission peak having the highest intensity has an emission maximum Amax at about 632.7 nm. A dominant wavelength λ_{D} is at about 617.7 nm.

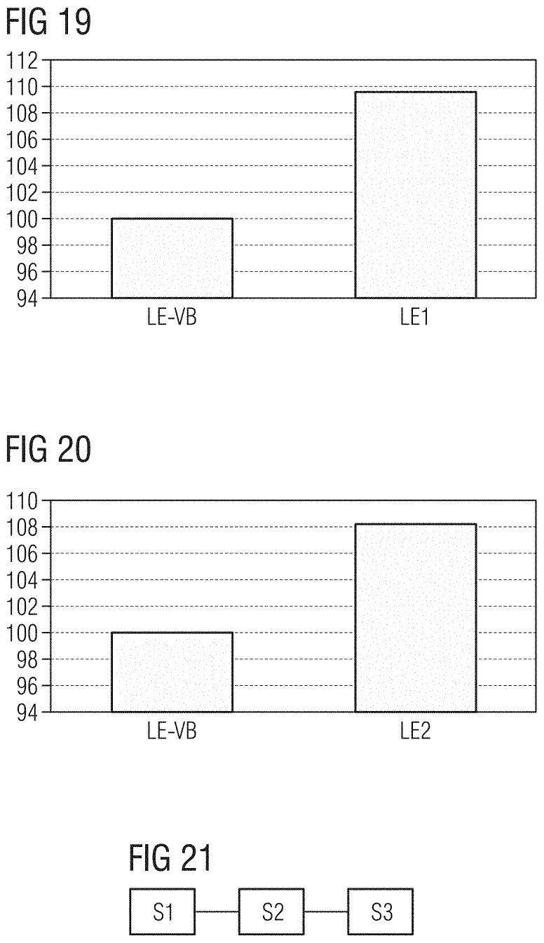

FIG. 19 shows the relative luminous efficacy of radiation LE1 of the luminophore 1, according to the working example CaZrF₆:Mn. By comparison, the relative luminous efficacy of radiation of the comparative example LE-VB of the luminophore K₂SiF₆:Mn is shown. The relative luminous efficacy of radiation LE1 of the luminophore 1 according to the working example CaZrF₆:Mn, by comparison with the relative luminous efficacy of radiation of the comparative example LE-VB, has a gain of nearly 10%.

FIG. 20 shows the relative luminous efficacy of radiation LE2 of the luminophore 1, according to the working example CaHfF₆:Mn. By comparison, the relative luminous efficacy of radiation of the comparative example LE-VB is shown. The luminophore 1 having the formula CaHfF₆:Mn, by comparison with the comparative example LE-VB, has a gain of nearly 10% in the relative luminous efficacy of radiation. The values for FIGS. 19 and 20 are likewise shown in table 2a.

Tables 2a-2d list of the luminous efficacies of radiation LER, the relative luminous efficacies of radiation LER, the emission maxima λₘₐₓ, the dominant wavelengths λ_{D} and the color loci CIE x and CIE y for the luminophores 1 according to the working examples CaZrF₆:Mn, CaHfF₆:Mn, SrTiF₆:Mn, ZnHfF₆:Mn, CaGeF₆:Mn, CaPbF₆:Mn, SrSnF₆:Mn, BaPbF₆:Mn, ZnSnF₆:Mn, MgGeF₆:Mn, CdPbF₆:Mn, ZnPbF₆:Mn, MgPbF₆:Mn, CdHfF₆:Mn, CaSnF₆:Mn, ZnZrF₆:Mn and the comparative example K₂SiF₆:Mn. The results from tables 2a-2d show that the inventive luminophores 1 having the formula CaZrF₆:Mn, CaHfF₆:Mn, SrTiF₆:Mn, ZnHfF₆:Mn, CaGeF₆:Mn, CaPbF₆:Mn, SrSnF₆:Mn, ZnSnF₆:Mn, MgGeF₆:Mn, CdPbF₆:Mn, ZnPbF₆:Mn, MgPbF₆:Mn, CdHfF₆:Mn, CaSnF₆:Mn and ZnZrF₆:Mn have a lower dominant wavelength compared to the comparative example K₂SiF₆:Mn. BaPbF₆:Mn, by contrast, has a greater dominant wavelength K₂SiF₆:Mn. In addition, the luminophores 1 having the formula CaZrF₆:Mn, CaHfF₆:Mn, CaPbF₆:Mn, SrSnF₆:Mn, CdPbF₆:Mn and mgPbF₆:Mn have a higher luminous efficacy of radiation than K₂SiF₆:Mn.

TABLE 2a
Optical data of the luminophores 1 having the formula CaZrF₆:
Mn, CaHfF₆: Mn, SrTiF₆: Mn, ZnHfF₆: Mn and K₂SiF₆: Mn

| | CaZrF₆: | CaHfF₆: | SrTiF₆: | ZnHfF₆: | K₂SiF₆: |
|---|---|---|---|---|---|
| | Mn | Mn | Mn | Mn | Mn |
| LER/lm | 222.2 | 219.3 | 190.7 | 194.9 | 202.7 |
| W_{opt.}⁻¹ | | | | | |
| Rel. | 109.6 | 108.2 | 94.1 | 96.2 | 100 |
| LER/% | | | | | |
| λₘₐₓ/nm | 628.3 | 628.3 | 628.4 | 632.7 | 630.8 |
| λ_{D}/nm | 615.4 | 617.2 | 612.7 | 617.7 | 619.6 |
| CIE x | 0.681 | 0.685 | 0.674 | 0.687 | 0.691 |
| CIE y | 0.319 | 0.315 | 0.326 | 0.313 | 0.309 |

TABLE 2b
Optical data of the luminophores 1 having the formula CaGeF₆:
Mn, CaPbF₆: Mn, SrSnF₆: Mn, BaPbF₆: Mn and K₂SiF₆: Mn

| | CaGeF₆: | CaPbF₆: | SrSnF₆: | BaPbF₆: | K₂SiF₆: |
|---|---|---|---|---|---|
| | Mn | Mn | Mn | Mn | Mn |
| LER/lm | | 213.4 | 228.6 | 191.4 | 202.7 |
| W_{opt.}⁻¹ | | | | | |
| Rel. | | 105 | 113 | 94 | 100 |
| LER/% | | | | | |
| λₘₐₓ/nm | 628.6 | 629.1 | 626.6 | 632.5 | 630.8 |
| λ_{D}/nm | 597.7 | 618.6 | 617.2 | 620.6 | 619.6 |
| CIE x | 0.616 | 0.689 | 0.685 | 0.693 | 0.691 |
| CIE y | 0.383 | 0.311 | 0.314 | 0.307 | 0.309 |

TABLE 2c
Optical data of the luminophores 1 having the formula
ZnSnF₆: Mn, MgGeF₆: Mn, CdPbF₆: Mn,
ZnPbF₆: Mn and K₂SiF₆: Mn

| | ZnSnF₆: | MgGeF₆: | CdPbF₆: | ZnPbF₆: | K₂SiF₆: |
|---|---|---|---|---|---|
| | Mn | Mn | Mn | Mn | Mn |
| LER/lm | 202.3 | 185.6 | 206.8 | 181 | 202.7 |
| W_{opt.}⁻¹ | | | | | |
| Rel. | 100 | 92 | 102 | 89 | 100 |
| LER/% | | | | | |
| λₘₐₓ/nm | 632.6 | 632.0 | 631.5 | 632.8 | 630.8 |
| λ_{D}/nm | 615.5 | 614.5 | 615.7 | 616.6 | 619.6 |
| CIE x | 0.681 | 0.679 | 0.682 | 0.684 | 0.691 |
| CIE y | 0.318 | 0.321 | 0.318 | 0.316 | 0.309 |

TABLE 2d
Optical data of the luminophores 1 having the
formula MgPbF₆: Mn, CdHfF₆: Mn, CaSnF₆:
Mn, ZnZrF₆: Mn and K₂SiF₆: Mn

| | MgPbF₆: | CdHfF₆: | ZnZrF₆: | CaSnF₆: | K₂SiF₆: |
|---|---|---|---|---|---|
| | Mn | Mn | Mn | Mn | Mn |
| LER/lm | 205.2 | | 195.1 | 229.9 | 202.7 |
| W_{opt.}⁻¹ | | | | | |
| Rel. | 101 | | 96 | 113 | 100 |
| LER/% | | | | | |
| λₘₐₓ/nm | 633.0 | 627.3 | 632.8 | 628.5 | 630.8 |
| λ_{D}/nm | 613.3 | 609.9 | 616.5 | 609.0 | 619.6 |
| CIE x | 0.675 | 0.665 | 0.684 | 0.663 | 0.691 |
| CIE y | 0.324 | 0.334 | 0.316 | 0.337 | 0.309 |

In the process according to the working example of FIG. 21, in a first process step S1, a stoichiometric composition selected from the group of the reactants calcium fluoride, hafnium(IV) oxide, manganese(II) chloride tetrahydrate, zinc chloride, strontium carbonate, titanium(IV) sulfide, germanium(IV) oxide, lead(II) chloride, tin(II) chloride dihydrate, barium fluoride, zinc carbonate, magnesium fluoride, cadmium chloride, cadmium fluoride, calcium permanganate tetrahydrate and/or zirconyl chloride octahydrate is provided. The reactants are mixed homogeneously. Subsequently, the resultant reaction mixture is introduced into a corundum boat, which is inserted into a tubular furnace. 5% by volume to 10% by volume of F₂ in argon is passed through the tubular furnace.

In a next process step S2, the reaction mixture is heated stepwise in the furnace. This means that the reaction mixture is heated at at least one heating rate to at least one intermediate temperature and kept at an intermediate temperature for at least one hold time. Subsequently, the reaction mixture is cooled to room temperature by a cooling step and mixed.

In a further process step S3, the reaction mixture is again inserted into the tubular furnace and heated stepwise. The reaction mixture is heated at at least one heating rate to at least one intermediate temperature or a maximum temperature and kept at an intermediate temperature for maximum temperature for at least one hold time.

The heating here is a dry high-temperature method. This means that no additional solvents or acids are added in the course of heating. The hazard potential resulting from the addition of an acid, especially a hydrofluoric acid solution, is accordingly avoided.

Preparation of the Luminophore 1 According to the Working Example CaZrF₆:Mn

A stoichiometric composition of the reactants calcium fluoride (780.8 mg, 10 mmol), zirconyl chloride octahydrate (3.144 g, 9.8 mmol) and manganese(II) chloride tetrahydrate (39.5 mg, 0.2 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./min), and this intermediate temperature is kept constant for one hour. The stepwise increase in the intermediate temperature and the hold times are repeated until the temperature reaches 370° C. The intermediate temperature is increased at 4° C./min to 400° C. within three days. After a hold time of five further days, the reaction mixture is cooled down to a minimum temperature of 30° C., crushed using a glassy carbon mortar and pestle, and put back in the furnace. The furnace is heated up again to 400° C. at a heating rate of 4° C./min and, after two further days, the intermediate temperature is increased at 4° C./min to a maximum temperature of 450° C. and kept at that maximum temperature for a further day. Subsequently, the reaction mixture is removed from the oven and cooled down, and the luminophore 1 having the formula CaZrF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaZrF₆:Mn by the process in aqueous HF which is otherwise customary in industry for complex fluoride luminophores.

Preparation of the Luminophore 1 According to the Working Example CaHfF₆:Mn

A stoichiometric composition of the reactants calcium fluoride (78.3 mg, 1 mmol), hafnium(IV) oxide (199.9 mg, 0.95 mmol) and manganese(II) chloride tetrahydrate (9.6 mg, 0.05 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./min), and this intermediate temperature is kept constant for one hour. The stepwise increase in the intermediate temperature and the hold times are repeated until the temperature reaches 370° C. After six days, the reaction mixture is cooled down to a minimum temperature of 30° C. Subsequently, the reaction mixture is removed from the furnace, crushed using a glassy carbon mortar and pestle, and put back in the furnace. The furnace is heated up again to 400° C. at a heating rate of 4° C./min and, after five further days, the reaction mixture is cooled down to a minimum temperature of 30° C., crushed with a mortar and pestle and subjected to heat treatment at 450° C. for a further 14 days at 450° C. in a fluorine stream. The luminophore 1 having the formula CaHfF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaHfF₆:Mn by the process in aqueous HF which is otherwise customary in industry for complex fluoride luminophores.

Preparation of Luminophore 1 According to the Working Example SrTiF₆:Mn

A stoichiometric composition of the reactants strontium carbonate (590.3 mg, 4 mmol), titanium(IV) sulfide (443.0 mg, 3.96 mmol) and manganese(II) chloride tetrahydrate (10.3 mg, 0.04 mmol) is mixed intimately in an agate mortar and introduced into a corundum boat. This corundum boat is placed in a corundum tube heatable by a tubular furnace, through which 10 ml/min of 10% by volume of F₂ in argon is passed. The intermediate temperature is increased to 100° C. (5° C./h), and this intermediate temperature is maintained for 20 hours. The stepwise increase in the intermediate temperature by 100° C. each time (10° C./h) and the hold times (10 hours) are repeated until the temperature reaches 300° C. After four days, the reaction mixture is cooled down to a minimum temperature of 30° C., and the reaction mixture is removed from the furnace, crushed using a glassy carbon mortar and pestle and put back in the furnace. The furnace is heated again to 300° C. at a heating rate of 4° C./min and the reaction mixture is reacted again with a gas stream of 10 ml/min of 5% by volume of F₂ in argon for a further 10 days. The luminophore 1 having the formula SrTiF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaZrF₆:Mn by the process in aqueous HF which is otherwise customary in industry for complex fluoride luminophores.

Preparation of the Luminophore 1 According to the Working Example ZnHfF₆:Mn

A stoichiometric composition of the reactants zinc chloride (135.1 mg, 1 mmol), hafnium(IV) oxide (200.5 mg, 0.95 mmol) and manganese(II) chloride tetrahydrate (11.8 mg, 0.05 mmol) is mixed intimately in an agate mortar and introduced into a corundum boat. This corundum boat is placed in a corundum tube heatable by a tubular furnace, through which 10% by volume of F₂ in argon is passed. The intermediate temperature is increased from 30° C. by 20° C. (0.33° C./min), and this intermediate temperature is kept constant for one hour. The stepwise increase in the intermediate temperature and the hold times are repeated until the temperature reaches 370° C. After a hold time of two days, the furnace is cooled down to a minimum temperature of 30° C., the reaction mixture is removed, crushed using a glassy carbon mortar and pestle, and put back in the furnace. The furnace is heated up again to 400° C. at a heating rate of 4° C./min and the reaction mixture is fluorinated for a further four days, before being cooled down again to 30° C. and crushed with a mortar and pestle. The reaction mixture is put back in the furnace and heated at 4° C./min to a maximum temperature of 450° C., and the reaction mixture is subjected to heat treatment in a fluorine stream for a further four days. The luminophore 1 having the formula ZnHfF₆:Mn is obtained.

The synthesis is thus a dry high-temperature process, in which it is possible to dispense with the use of hydrofluoric acid solutions.

Preparation of the Luminophore 1 According to the Working Example CaGeF₆:Mn

For the synthesis of CaGeF₆:Mn, calcium fluoride (236.5 mg, 3.03 mmol), germanium(IV) oxide (GeO₂, 310.6 mg, 2.97 mmol) and manganese(II) chloride tetrahydrate (MnCl₂.4H₂O, 8.0 mg, 0.04 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 13 days, the furnace is cooled down to a temperature of 30° C., and the reaction mixture is removed, crushed using a glassy carbon mortar and pestle, and put back in the furnace. The reaction mixture is heated in the furnace at 4° C./min to a temperature of 400° C. and subjected to heat treatment in a fluorine stream for a further 15 days. The luminophore 1 having the formula CaGeF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaGeF₆:Mn by the process in aqueous HF which is otherwise customary in industry for complex fluoride luminophores.

Preparation of the Luminophore 1 According to the Working Example CaPbF₆:Mn

Calcium fluoride (CaF₂, 78.7 mg, 1.00 mmol), lead(II) chloride (PbCl₂, 278.7 mg, 1.00 mmol) and manganese(II) chloride tetrahydrate (MnCl₂.4H₂O, 2.2 mg, 0.01 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 6 days, the furnace is cooled down to a temperature of 30° C., and the reaction mixture is removed, crushed using a glassy carbon mortar and pestle, and put back in the furnace. The reaction mixture is heated in the furnace at 4° C./min to a temperature of 400° C. and subjected to heat treatment in a fluorine stream for a further 8 days. The luminophore 1 having the formula CaPbF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaPbF₆:Mn by the process in aqueous HF which is otherwise customary in industry for complex fluoride luminophores. Furthermore, lead(IV) in quantitative analysis serves as a detection reagent for manganese ions, which are oxidized under acidic conditions to give the pink permanganate ion. Therefore, the presence of Mn(IV) under acidic conditions alongside Pb(IV) is not possible. Accordingly, it is not possible to prepare CaPbF₆:Mn by the process in aqueous HF which is otherwise customary in industry for complex fluoride luminophores.

Preparation of the Luminophore 1 According to the Working Example SrSnF₆:Mn

For the synthesis of SrSnF₆:Mn, strontium carbonate (SrCO₃, 297.6 mg, 2.02 mmol), tin(II) chloride dihydrate (SnCl₂.2H₂O, 441.4 mg, 1.96 mmol) and manganese(II) chloride tetrahydrate (MnCl₂.4H₂O, 9.5 mg, 0.05 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 7 days, the furnace is cooled down to a minimum temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 16 days. The luminophore 1 having the formula SrSnF₆:Mn is obtained.

The synthesis is thus a dry high-temperature process, in which it is possible to dispense with the use of hydrofluoric acid solutions. Owing to the sparing solubility of CaF₂ in water, it is not possible to prepare SrSnF₆:Mn by the process in aqueous HF which is otherwise customary in industry for complex fluoride luminophores.

Preparation of the Luminophore 1 According to the Working Example BaPbF₆: Mn

Barium fluoride (BaF₂, 175.9 mg, 1.01 mmol), tin(II) chloride (SnCl₂, 275.3 mg, 0.99 mmol) and manganese(II) chloride tetrahydrate (MnCl₂.4H₂O, 1.5 mg, 0.01 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 6 days, the furnace is cooled down to a minimum temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 8 days. The luminophore 1 having the formula BaPbF₆:Mn is obtained.

The synthesis is thus a dry high-temperature process, in which it is possible to dispense with the use of hydrofluoric acid solutions. Owing to the sparing solubility of BaF₂ in water, and since Mn(IV) does not exist alongside Pb(IV) in aqueous hydrofluoric acid, it is not possible to prepare BaPbF₆:Mn by the process in aqueous HF which is otherwise customary in industry for complex fluoride luminophores.

Preparation of the Luminophore 1 According to the Working Example ZnSnF₆:Mn

Zinc carbonate (ZnCO₃, 252.8 mg, 2.02 mmol), tin(II) chloride dihydrate (SnCl₂.2H₂O, 442.5 mg, 1.96 mmol) and manganese(II) chloride tetrahydrate (MnCl₂.4H₂O, 8.0 mg, 0.04 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 7 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 5 days. After cooling in the furnace to a temperature of 30° C., the reaction mixture is removed, crushed using a glassy carbon mortar and pestle, and put back in the furnace. The furnace is heated at 4° C./min up to 400° C., and the reaction mixture is subjected to heat treatment in a fluorine stream for a further 11 days. The luminophore 1 having the formula ZnSnF₆:Mn is obtained.

The synthesis is thus a dry high-temperature process, in which it is possible to dispense with the use of hydrofluoric acid solutions.

Preparation of the Luminophore 1 According to the Working Example MgGeF₆:Mn

Magnesium fluoride (MgF₂, 61.2 mg, 0.98 mmol), germanium(IV) oxide (GeO₂, 102.4 mg, 0.98 mmol) and manganese(II) chloride tetrahydrate (MnCl₂.4H₂O, 4.1 mg, 0.02 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 7 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 5 days. The luminophore 1 having the formula MgGeF₆:Mn is obtained.

The synthesis is thus a dry high-temperature process, in which it is possible to dispense with the use of hydrofluoric acid solutions. Owing to the sparing solubility of MgF₂ in water, it is not possible to prepare SrSnF₆:Mn by the process in aqueous HF which is otherwise customary in industry for complex fluoride luminophores.

Preparation of the Luminophore 1 According to the Working Example CdPbF₆: Mn

Cadmium chloride (CdCl₂, 91.8 mg, 0.50 mmol), lead(II) chloride (PbCl₂, 137.4 mg, 0.49 mmol) and manganese(II) chloride tetrahydrate (MnCl₂.4H₂O, 3.1 mg, 0.02 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 6 days, the furnace is cooled down to a temperature of 30° C., and the reaction mixture is removed, crushed using a glassy carbon mortar and pestle, and put back in the furnace. The furnace is heated at 4° C./min up to 400° C., and the reaction mixture is subjected to heat treatment in a fluorine stream for a further 26 days. The luminophore 1 having the formula CdPbF₆:Mn is obtained.

The synthesis is thus a dry high-temperature process, in which it is possible to dispense with the use of hydrofluoric acid solutions. Owing to the oxidation of manganese(IV) under acidic conditions to manganese(VII), it is not possible to prepare CdPbF₆:Mn by the process in aqueous HF which is otherwise customary in industry for complex fluoride luminophores.

Preparation of the Luminophore 1 According to the Working Example ZnPbF₆:Mn

Zinc carbonate (ZnCO₃, 63.7 mg, 0.51 mmol), lead(II) chloride (PbCl₂, 135.2 mg, 0.49 mmol) and manganese(II) chloride tetrahydrate (MnCl₂.4H₂O, 2.5 mg, 0.01 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 6 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 7 days. The luminophore 1 having the formula ZnPbF₆:Mn is obtained.

The synthesis is thus a dry high-temperature process, in which it is possible to dispense with the use of hydrofluoric acid solutions. Owing to the oxidation of manganese(IV) under acidic conditions to manganese(VII), it is not possible to prepare ZnPbF₆:Mn by the process in aqueous HF which is otherwise customary in industry for complex fluoride luminophores.

Preparation of the Luminophore 1 According to the Working Example MgPbF₆:Mn

Magnesium fluoride (MgF₂, 33.1 mg, 0.53 mmol), lead(II) chloride (PbCl₂, 136.3 mg, 0.49 mmol) and manganese(II) chloride tetrahydrate (MnCl₂.4H₂O, 4.0 mg, 0.02 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 4 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 9 days. The luminophore 1 having the formula MgPbF₆:Mn is obtained.

The synthesis is thus a dry high-temperature process, in which it is possible to dispense with the use of hydrofluoric acid solutions. Owing to the sparing solubility of MgF₂ in water and since Mn(IV) does not exist alongside Pb(IV) under acidic conditions, it is not possible to prepare ZnPbF₆:Mn by the process in aqueous HF which is otherwise customary in industry for complex fluoride luminophores.

Preparation of the Luminophore 1 According to the Working Example CdHfF₆:Mn

Cadmium fluoride (CdF₂, 151.4 mg, 1.01 mmol) and hafnium(IV) oxide (HfO₂, 211.4 mg, 1.00 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. The temperature is maintained for 10 h and then increased to 450° C. within 10 h. After a hold time of 12 days, the furnace is cooled down to a temperature of 30° C., and the reaction mixture is removed, crushed using a glassy carbon mortar and pestle, and put back in the furnace. The furnace is heated at 4° C./min up to 450° C., and the reaction mixture is subjected to heat treatment in a fluorine stream for a further 13 days. The luminophore 1 having the formula CdHfF₆:Mn is obtained. The input of manganese ions is attributable to previous reactions and a manganese species that has remained as a result, which reacts at the synthesis temperature to give volatile manganese(IV) fluoride and is deposited on the CdHfF₆.

The synthesis is thus a dry high-temperature process, in which it is possible to dispense with the use of hydrofluoric acid solutions.

Preparation of the Luminophore 1 According to the Working Example ZnZrF₆:Mn

Zinc carbonate (ZnCO₃, 124.5 mg, 0.99 mmol), zirconyl chloride octahydrate (ZrOCl₂.8H₂O, 316.0 mg, 0.98 mmol) and manganese(II) chloride tetrahydrate (MnCl₂.4H₂O, 3.6 mg, 0.02 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 8 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 10 days. The luminophore 1 having the formula ZnZrF₆:Mn is obtained.

The synthesis is thus a dry high-temperature process, in which it is possible to dispense with the use of hydrofluoric acid solutions.

Preparation of the Luminophore 1 According to the Working Example CaSnF₆:Mn

Calcium fluoride (CaF₂, 154.4 mg, 1.97 mmol), tin(II) chloride dihydrate (SnCl₂.2H₂O, 446.7 mg, 1.98 mmol) and calcium permanganate tetrahydrate (Ca(MnO₄)₂.4H₂O, 3.0 mg, 0.01 mmol) are mixed intimately in an agate mortar and introduced into a corundum boat. This corundum boat is placed in a corundum tube heatable by a tubular furnace, through which 10% by volume of F₂ in argon is passed at 5 ml/min. The temperature is increased from 30° C. to 100° C. within 5 h, which is maintained for 20 h, before the temperature is increased stepwise by 100° C. (10° C./h, hold time 10 h) up to 400° C. After a hold time of 18 days, the furnace is cooled down to a temperature of 30° C., and the reaction mixture is removed, crushed using a glassy carbon mortar and pestle, and put back in the furnace. The reaction mixture is heated in the furnace at 4° C./min up to 400° C., and the reaction mixture is subjected to heat treatment in a fluorine stream for a further 13 days. The luminophore 1 having the formula CaSnF₆:Mn is obtained.

The synthesis is thus a dry high-temperature process, in which it is possible to dispense with the use of hydrofluoric acid solutions. Owing to the sparing solubility of CaF₂ in water, it is not possible to prepare CaZrF₆:Mn by the process in aqueous HF which is otherwise customary in industry for complex fluoride luminophores.

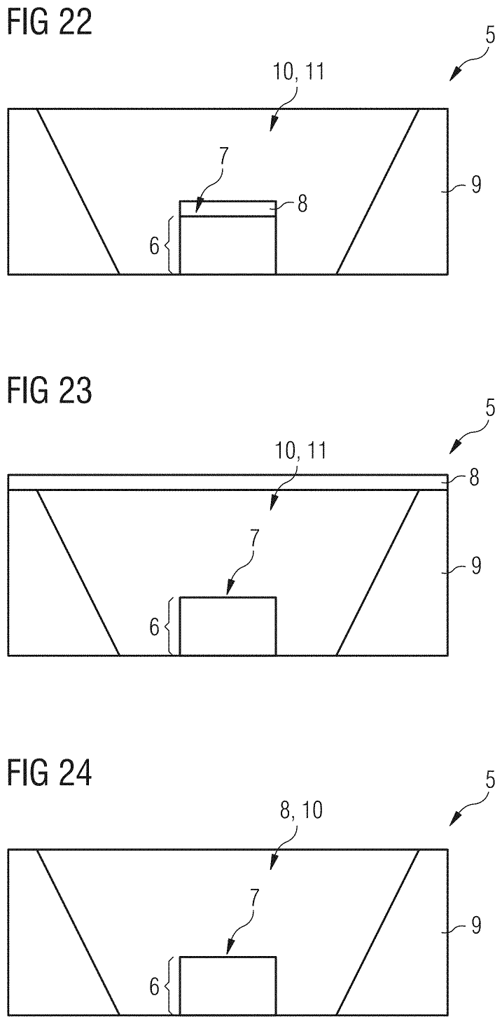

FIG. 22 shows a schematic section diagram of a radiation-emitting component 5 in one working example, having a semiconductor chip 6 which emits primary radiation in operation of the radiation-emitting component 5. The semiconductor chip 6 comprises an active layer sequence and an active region (not shown explicitly here), which serves to generate the primary radiation. The primary radiation is electromagnetic radiation of a first wavelength range. The primary radiation is preferably electromagnetic radiation having wavelengths in the visible region, for example in the blue region. The primary radiation is emitted by the radiation exit face 7. This generates a beam path, meaning that the primary radiation follows a beam path.

A conversion element 8 is disposed in the beam path of the primary radiation emitted by the semiconductor chip 6. The conversion element 8 is set up to absorb the primary radiation and convert it at least partly to a secondary radiation having a second wavelength range. In particular, the secondary radiation has a longer wavelength than the primary radiation absorbed.

The conversion element 8 includes a luminophore 1 having the general formula A_{z}EₑX₆:RE. More particularly, the conversion element 8 may include the luminophore 1 having the formula CaZrF₆:Mn, CaHfF₆:Mn, SrTiF₆:Mn, ZnHfF₆:Mn, CaGeF₆:Mn, CaPbF₆:Mn, SrSnF₆:Mn, BaPbF₆:Mn, ZnSnF₆:Mn, MgGeF₆:Mn, CdPbF₆:Mn, ZnPbF₆:Mn, MgPbF₆:Mn, CdHfF₆:Mn, CaSnF₆:Mn and/or ZnZrF₆:Mn. The luminophore 1 may be embedded into a matrix material. The matrix material is, for example, a silicone, a polysiloxane, an epoxy resin or glass. Alternatively, the conversion element 8 may be free of any matrix material. In that case, the conversion element 8 may consist of the luminophore 1, for example of a ceramic of the luminophore 1.

Alternatively, the conversion element 8 may include a second luminophore that converts primary radiation, for example to yellow or green secondary radiation. The combination of the blue primary radiation, the red secondary radiation and the yellow or green secondary radiation can generate warm white mixed light having a high color rendering index Rₐ.

In the working example shown in FIG. 22, the semiconductor chip 6 and the conversion element 8 are embedded in a recessed 10 in a housing 9. For better stabilization and for protection of the semiconductor chip 6 and of the conversion element 8, the recess 10 of the housing 9 may be filled with an encapsulant 11.

More particularly, the recess 10 is filled completely with the encapsulant 11, and the semiconductor chip 6 and the conversion element 8 are fully enveloped by the encapsulant 11.

The conversion element 8 may, as shown in FIG. 22, be arranged in direct mechanical contact atop the semiconductor chip 6. In particular, the radiation exit face 7 forms the common face between the conversion element 8 and the semiconductor chip 6. Alternatively, there may be further layers, for example adhesive layers, between the semiconductor chip 6 and the conversion element 8.

In the working example shown in FIG. 23, the conversion element 8 is disposed at a distance from the semiconductor chip 6. In that case, an encapsulant 11 may be disposed between the semiconductor chip 6 and the conversion element 8. Alternatively, the recess 10 between the semiconductor chip 6 and the conversion element 8 may also be free of any encapsulant 11 or further layers or components.

In the working example shown in FIG. 24, the conversion element 8 is disposed in a recessed 10. The semiconductor chip 6 is embedded into the conversion element 8. The conversion element 8 comprises the luminophore 1 and the matrix material, which is silicone, for example. Further luminophores may be introduced into the conversion element 8.

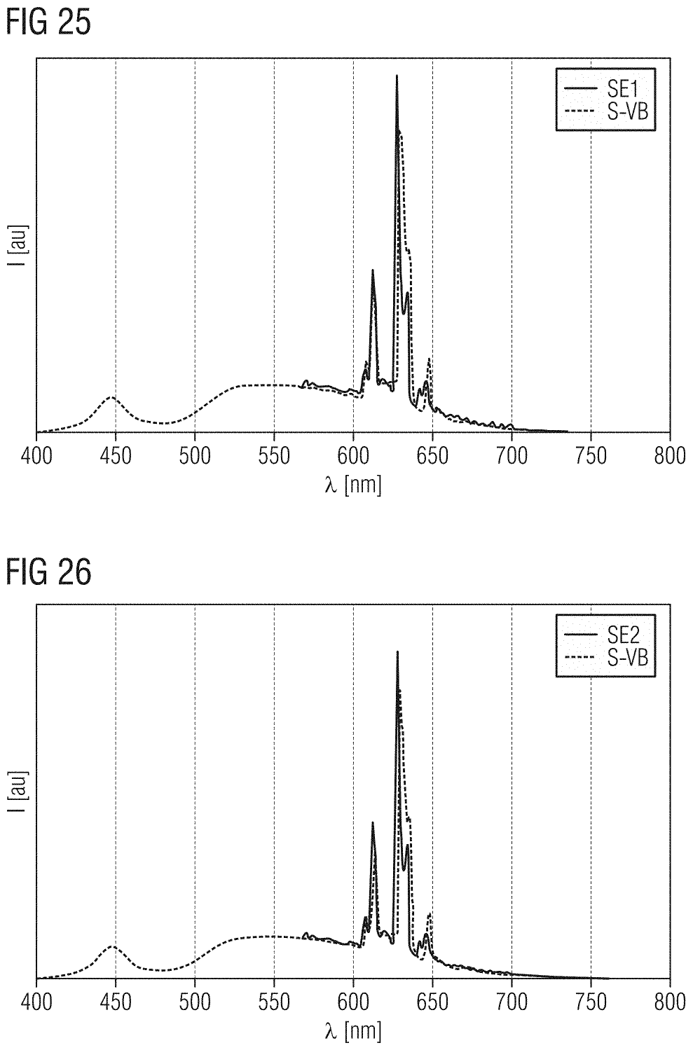

FIGS. 25 and 26 each show simulated LED emission spectra with the luminophore 1 and with the comparative luminophore of the comparative example S-VB. Here, both for the luminophore 1 and for the comparative example, LED spectra with a color temperature of about 3000 K were simulated. Relative intensity I in arbitrary units is plotted against the wavelength λ in nm. Here, LED emission spectrum were simulated both for the luminophore 1 and for the comparative luminophore. The second luminophore was assumed to be a green-emitting luminophore (Lu,Y)₃Al₅O₁₂:Ce. The green-emitting luminophore (Lu,Y)₃Al₅O₁₂:Ce was combined with a blue-emitting semiconductor chip 6 having a dominant wavelength λ_{D} of 455 nm and the emission spectrum of luminophore 1. In the simulated LED emission spectrum of the comparative example S-VB, rather than the red-emitting luminophore 1, the red-emitting comparative luminophore K₂SiF₆:Mn was used.

In FIG. 25, the red luminophore used was luminophore 1 according to the working example CaZrF₆:Mn. It is clearly apparent that the LED emission spectrum SE1 with luminophore 1 of the formula CaZrF₆:Mn has been shifted to shorter wavelengths compared to the comparative example S-VB.

FIG. 26 differs merely in the use of the luminophore 1. In FIG. 26, for the simulation of the luminophore 1 according to the working example, CaHfF₆:Mn was used. Here too, a distinct shift to shorter wavelengths of the LED emission spectrum SE2 with the luminophore 1 CaHfF₆:Mn is found by comparison with the comparative example S-VB.

Table 3 compares the optical data of the simulated LED emission spectrum with the luminophores of the working examples CaZrF₆:Mn and CaHfF₆:Mn and of the comparative example K₂SiF₆:Mn as red luminophore. The second luminophore was assumed to be a green-emitting luminophore (Lu,Y)₃Al₅O₁₂:Ce, and the semiconductor chip 6 was assumed to be a blue-emitting semiconductor chip 6 having a dominant wavelength λ_{D} of 455 nm.

TABLE 3
Optical data of the simulated LED emission spectrum with the
luminophores of the formula CaZrF₆: Mn, CaHfF₆: Mn
and K₂SiF₆: Mn as red luminophore.

| | CaZrF₆: Mn | CaHfF₆: Mn | K₂SiF₆: Mn |
|---|---|---|---|
| LER/lm W_{opt.}⁻¹ | 336.5 | 336.3 | 331.3 |
| Rel. LER/% | 102 | 102 | 100 |
| Rₐ | 92 | 92 | 89 |
| R₉ | 97 | 25 | 74 |
| CIE x | 0.437 | 0.437 | 0.437 |
| CIE y | 0.404 | 0.404 | 0.404 |
| CCT/K | 3008 | 2993 | 2996 |

By comparison with the comparative example with the red-emitting luminophore K₂SiF₆:Mn, the LEDs with the red-emitting luminophore 1 according to the working example CaZrF₆:Mn or with the red-emitting luminophore 1 according to the working example CaHfF₆:Mn have a higher luminous efficacy of radiation (LER) by 2%. In addition, for the same color locus, i.e. identical CIE x and CIE y, it is possible to achieve a color rendering index Rₐ which is three points better. Especially in the case of the R₉, which is a measure of the true rendering of saturated red hues, a much higher value is observed.

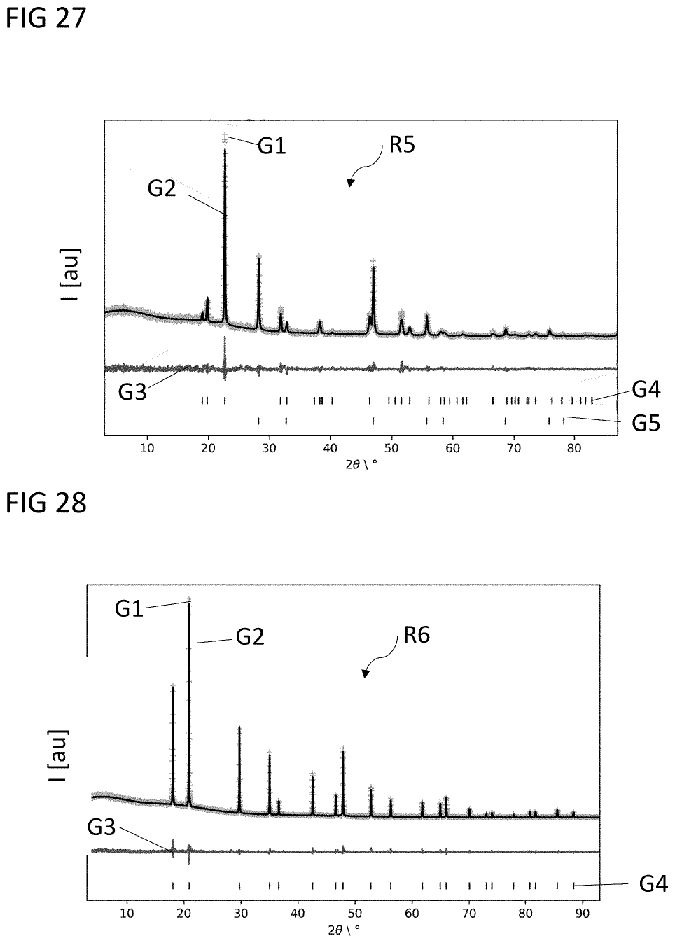

FIG. 27 shows a Rietveld-refined powder diffractogram R5 of the luminophore 1 according to the working example CaGeF₆:Mn. For this purpose, proceeding from the published crystal structure of LiSbF₆ [J. H. Burns, Acta Crystallogr. 1962, 15, 1098-1101] and the published cell parameters of CaGeF₆ (LiSbF₆ type) [D. Reinen, F. Steffens, Z. Anorg. Allg. Chem. 1978, 441, 63-82], a structure model was created, in which Sb is replaced by Ge and Li by Ca, and then refined. Good agreement of the calculated powder diffractogram G2 with the measured diffractogram G1 is apparent. As well as luminophore 1 having the formula CaGeF₆:Mn, CaF₂ is present as a crystalline, non-luminescent secondary phase (see G5, which shows the calculated reflection positions of CaF₂). It is thus possible to verify the crystal structure of the working example CaGeF₆:Mn. The crystal structure is isotypic with LiSbF₆.

FIG. 28 shows a Rietveld-refined powder diffractogram R6 of the luminophore 1 according to the working example CaPbF₆:Mn. For this purpose, proceeding from the published crystal structure of CaPbF₆ [R. Hoppe, J. Inorg. Nucl. Chem. 1958, 8, 437-440; R. Hoppe, K. Blinne, Z. Anorg. Allg. Chem. 1958, 293, 251-263] and the published structure of NaSbF₆ [G. Teufer, Acta Crystallogr. 1956, 9, 539-540], a structure model was created, in which Sb is replaced by Pb and Na by Ca, and then refined. Here too, good agreement of the calculated powder diffractogram G2 with the measured diffractogram G1 is apparent. It is thus possible to verify the crystal structure of the working example CaPbF₆:Mn. It is clearly apparent that there are no secondary crystalline phases. The crystal structure is isotypic with NaSbF₆.

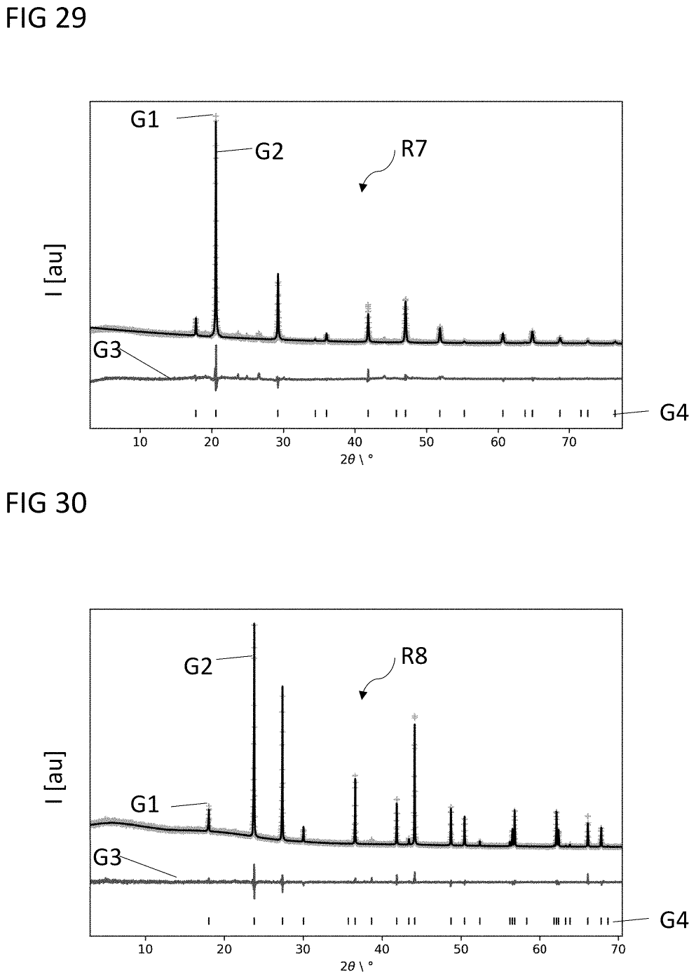

FIG. 29 shows a Rietveld-refined powder diffractogram R7 of the luminophore 1 according to the working example SrSnF₆:Mn. For this purpose, proceeding from the published crystal structure of SrSnF₆ [P. J. Moehs, H. M. Haendler, Inorg. Chem. 1968, 7, 2115-2118] and the published crystal structure of NaSbF₆ [G. Teufer, Acta Crystallogr. 1956, 9, 539-540], a structure model was created, in which Sb is replaced by Sn and Na by Sr, and then refined. Here too, good agreement of the calculated powder diffractogram G2 with the measured diffractogram G1 is apparent. It is thus possible to verify the crystal structure of the working example SrSnF₆:Mn. It is clearly apparent that there are no secondary crystalline phases. The crystal structure is isotypic with NaSbF₆.

FIG. 30 shows a Rietveld-refined powder diffractogram R8 of the luminophore 1 according to the working example BaPbF₆:Mn. For this purpose, proceeding from the published crystal structure of BaPbF₆ [R. Hoppe, J. Inorg. Nucl. Chem. 1958, 8, 437-440; R. Hoppe, K. Blinne, Z. Anorg. Allg. Chem. 1958, 293, 251-263] and the published structure of BaSiF₆ [J. L. Hoard, W. B. Vincent, J. Am. Chem. Soc. 1940, 62, 3126-3129], a structure model was created, in which Si is replaced by Pb, and then refined. Here too, good agreement of the calculated powder diffractogram G2 with the measured diffractogram G1 is apparent. It is thus possible to verify the crystal structure of the working example BaPbF₆:Mn. It is clearly apparent that there are no secondary crystalline phases. The crystal structure is isotypic with BaSiF₆.

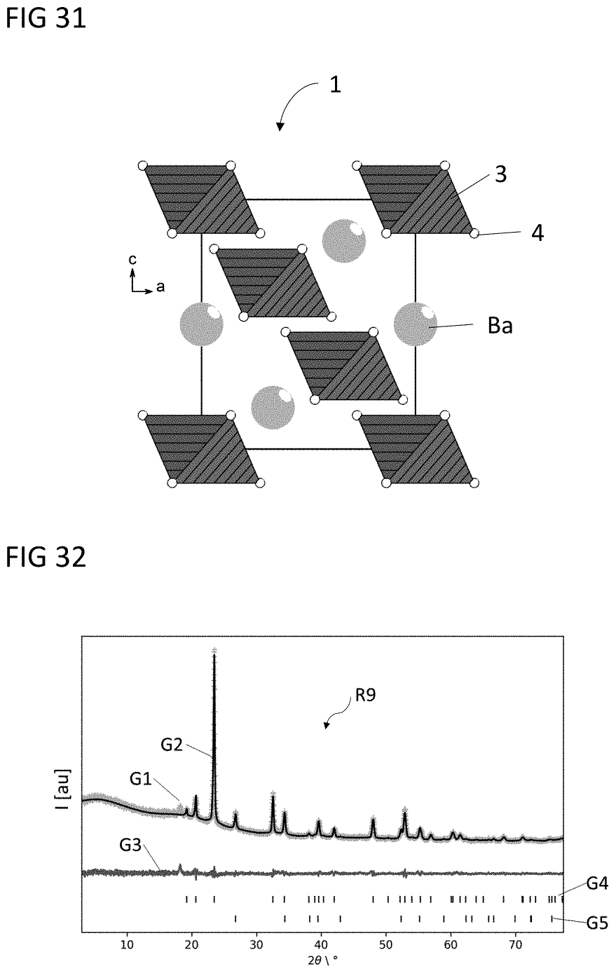

FIG. 31 shows a detail of the host lattice of the luminophore 1 A_{z}EₑX₆:RE according to the working example BaPbF₆:Mn in a schematic diagram in viewing direction in the [010] direction. The host lattice has a structure of a trigonal R3̅m space group. In the present case, the host lattice has a structure composed of a three-dimensional network of EX₆ octahedra or 3 with E=Pb and X=F, i.e. PbF₆ octahedra, and AX₁₂ with A=Ba and X=F cuboctahedra, i.e. BaF₁₂ cube octahedra. For clarity, not all octahedra and atoms are given a reference numeral, and the cuboctahedra are not shown.

FIGS. 32, 33, 34, 36 and 37 each show Le Bail-refined powder diffractograms of various working examples of the luminophore 1. Relative intensity I is plotted here in arbitrary units against the diffraction angle 2θ. The crosses shown in the powder X diffractogram are the measured reflections G1 of the working example of the luminophore 1. The dark gray line describes a difference diagram G3, and the black line describes a calculated powder diffractogram G2. The black marks G4 show the calculated reflection positions of the luminophore. G5 and G6 show the calculated reflection positions of any secondary crystalline phases.

FIG. 32 shows a Le Bail-refined powder diffractogram R9 of the luminophore 1 according to the working example ZnSnF₆:Mn. For this purpose, proceeding from the published structure of ZnSnF₆ (LiSbF₆ type) [P. J. Moehs, H. M. Haendler, Inorg. Chem. 1968, 7, 2115-2118; R. Hoppe, V. Wilhelm, B. Müller, Z. Anorg. Allg. Chem. 1972, 392, 1-9], the cell parameters were refined. Good agreement of the calculated powder diffractogram G2 with the measured diffractogram G1 is apparent. As well as ZnSnF₆:Mn, ZnF₂ is also present as a crystalline, non-luminescent secondary phase (see G5, which shows the calculated reflection positions of ZnF₂). It is thus possible to verify the crystal structure of the working example ZnSnF₆:Mn. The unit cell metrics and the crystal system of ZnSnF₆:Mn are comparable to those of LiSbF₆.

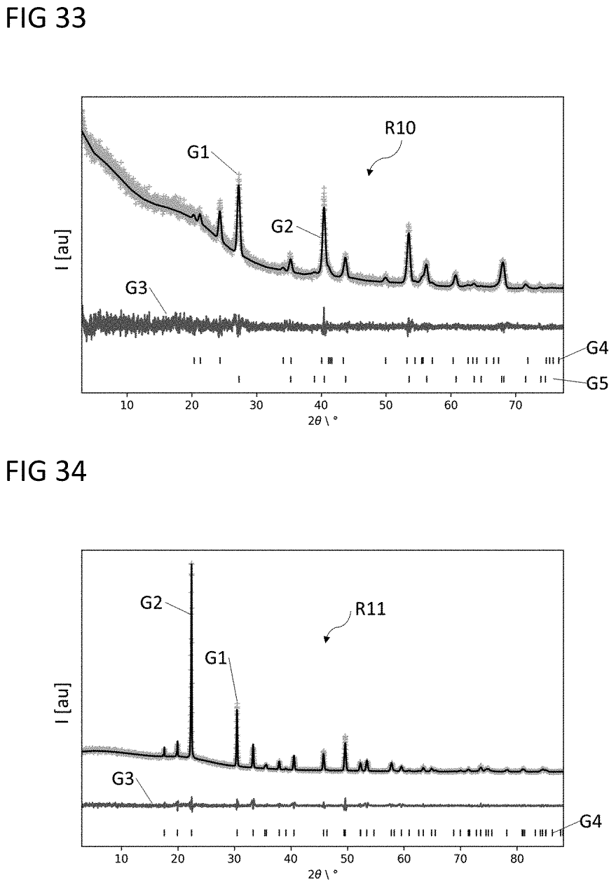

FIG. 33 shows a Le Bail-refined powder diffractogram R10 of the luminophore 1 according to the working example MgGeF₆:Mn. For this purpose, proceeding from the published structure of MgGeF₆ [D. Reinen, F. Steffens, Z. Anorg. Allg. Chem. 1978, 441, 63-82], the cell parameters were refined. Good agreement of the calculated powder diffractogram G2 with the measured diffractogram G1 is apparent. As well as MgGeF₆:Mn, MgF₂ is present as a crystalline, non-luminescent secondary phase (see G5, which shows the calculated reflection positions of MgF₂). It is thus possible to verify the crystal structure of the working example MgGeF₆:Mn. The unit cell metrics and the crystal system of MgGeF₆:Mn are comparable to those of LiSbF₆.

FIG. 34 shows a Le Bail-refined powder diffractogram R11 of the luminophore 1 according to the working example CdPbF₆:Mn. For this purpose, proceeding from the published structure of VF₃ [D. Reinen, F. Steffens, Z. Anorg. Allg. Chem. 1978, 441, 63-82], the cell parameters were refined. Good agreement of the calculated powder diffractogram G2 with the measured diffractogram G1 is apparent. It is clearly apparent that there is no secondary crystalline phases in the sample aside from CdPbF₆:Mn. It is thus possible to verify the crystal structure of the working example CdPbF₆:Mn. The unit cell metrics and the crystal system of CdPbF₆:Mn are comparable to those of VF₃.

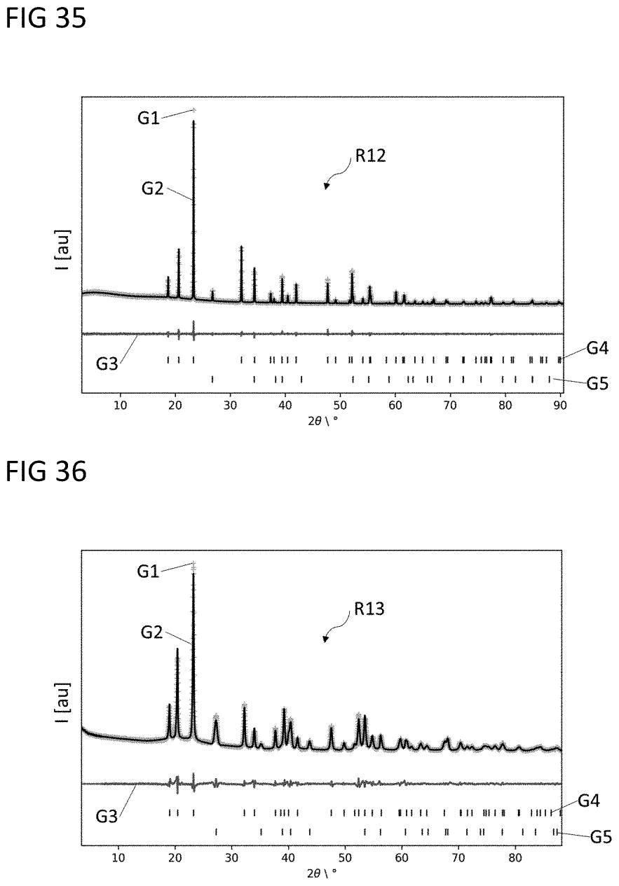

FIG. 35 shows a Rietveld-refined powder diffractogram R12 of the luminophore 1 according to the working example ZnPbF₆:Mn. For this purpose, refinement proceeded from the published structure of ZnPbF₆ [R. Homann, R. Hoppe, Z. Anorg. Allg. Chem. 1969, 368, 271-278]. Good agreement of the calculated powder diffractogram G2 with the measured diffractogram G1 is apparent. As well as ZnPbF₆:Mn, ZnF₂ is present as a crystalline, non-luminescent secondary phase (see G5, which shows the calculated reflection positions of ZnF₂). It is thus possible to verify the crystal structure of the working example ZnPbF₆:Mn. The unit cell metrics and the crystal system of ZnPbF₆:Mn are comparable to those of LiSbF₆.

FIG. 36 shows a Le Bail-refined powder diffractogram R13 of the luminophore 1 according to the working example MgPbF₆:Mn. For this purpose, proceeding from the published structure of MgPbF₆ [R. Homann, R. Hoppe, Z. Anorg. Allg. Chem. 1969, 368, 271-278], the cell parameters were refined. Good agreement of the calculated powder diffractogram G2 with the measured diffractogram G1 is apparent. As well as MgPbF₆:Mn, MgF₂ is present as a crystalline, non-luminescent secondary phase (see G5, which shows the calculated reflection positions of MgF₂). It is thus possible to verify the crystal structure of the working example MgPbF₆:Mn. The crystal structure is isotypic with LiSbF₆.

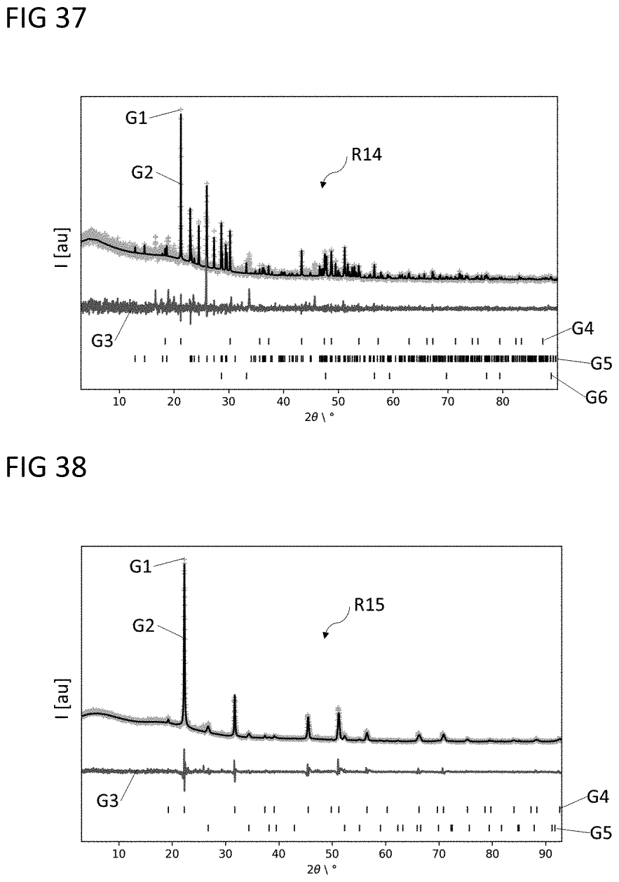

FIG. 37 shows a Le Bail-refined powder diffractogram R14 of the luminophore 1 according to the working example CdHfF₆:Mn. For this purpose, proceeding from the published structure of NaSbF₆ [G. Teufer, Acta Crystallogr. 1956, 9, 539-540], the cell parameters were refined. Good agreement of the calculated powder diffractogram G2 with the measured diffractogram G1 is apparent. As well as CdHfF₆:Mn, CdF₂ and HfF₄ are present as a crystalline, non-luminescent secondary phase (see G5 and G6, which show the calculated reflection positions of CdF₂ and HfF₄). It is thus possible to verify the crystal structure of the working example CdHfF₆:Mn. The unit cell metrics and the crystal system of CdHfF₆:Mn are comparable to those of NaSbF₆.

FIG. 38 shows a Rietveld-refined powder diffractogram R15 of the luminophore 1 according to the working example ZnZrF₆:Mn. For this purpose, proceeding from the published crystal structure of ZnZrF₆ [M. Poulain, J. Lucas, C. R. Seances Acad. Sci., Ser. C 1970, 822-824; V. Rodriguez, M. Gonzi, A. Tressaud, J. Grannec, J. P. Chaminade, J. L. Soubeyroux J. Phys.: Condens. Matter 1990, 2, 7373-7386] and the published crystal structure of NaSbFe [G. Teufer, Acta Crystallogr. 1956, 9, 539-540], a structure model was created, in which Sb is replaced by Zr and Na by Zn, and then refined. Good agreement of the calculated powder diffractogram G2 with the measured diffractogram G1 is apparent. As well as ZnZrF₆:Mn, ZnF₂ is present as a crystalline, non-luminescent secondary phase (see G5, which shows the calculated reflection positions of ZnF₂). It is thus possible to verify the crystal structure of the working example ZnZrF₆:Mn. The crystal structure is isotypic with NaSbF₆.

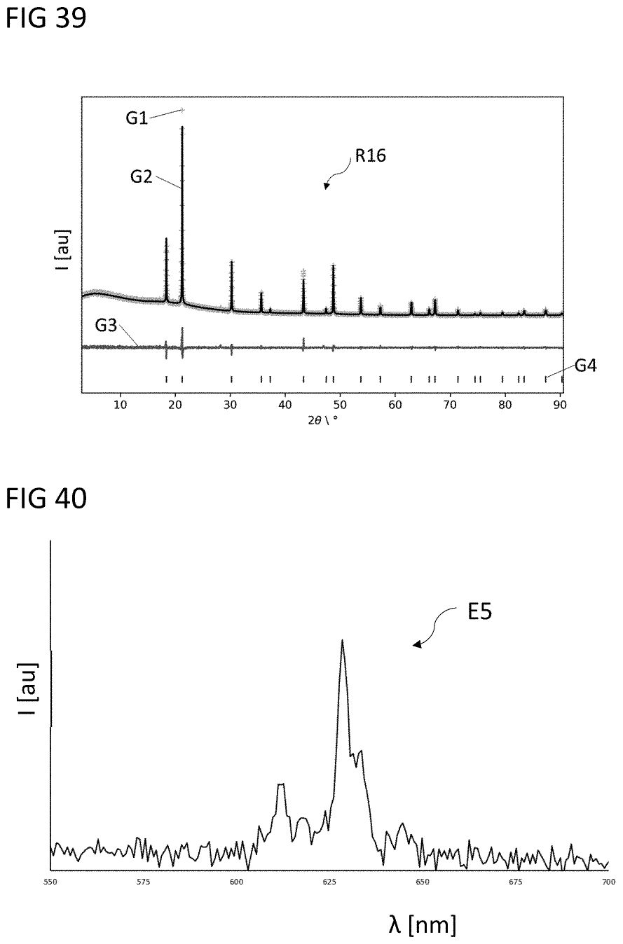

FIG. 39 shows a Rietveld-refined powder diffractogram R16 of the luminophore 1 according to the working example CaSnF₆:Mn. The starting point used for the refinement was the published structure of CaSnF₆ (NaSbF₆ type) [H. W. Mayer, D. Reinen, G. Heger, J. Solid State Chem. 1983, 50, 213-224]. It is clearly apparent that there is no secondary crystalline phase in the sample aside from the target compound. Good agreement of the calculated powder diffractogram G2 with the measured diffractogram G1 is also apparent. It is thus possible to verify the crystal structure of the working example CaSnF₆:Mn. The crystal structure is isotypic with NaSbF₆.

FIG. 40 shows an emission spectrum E5 of the working example CaGeF₆:Mn of the luminophore 1. The emission peak having the highest intensity has an emission maximum λₘₐₓ at 628.6 nm. A dominant wavelength λ_{D} is 597.7 nm. The emission of CaGeF₆:Mn is short-wave by about 2 nm compared to K₂SiF₆, and hence shifted toward the region of higher eye sensitivity (not shown), which results in a spectral gain. Advantageously, higher spectral efficiencies in LEDs are thus possible for general lighting and display backlighting.

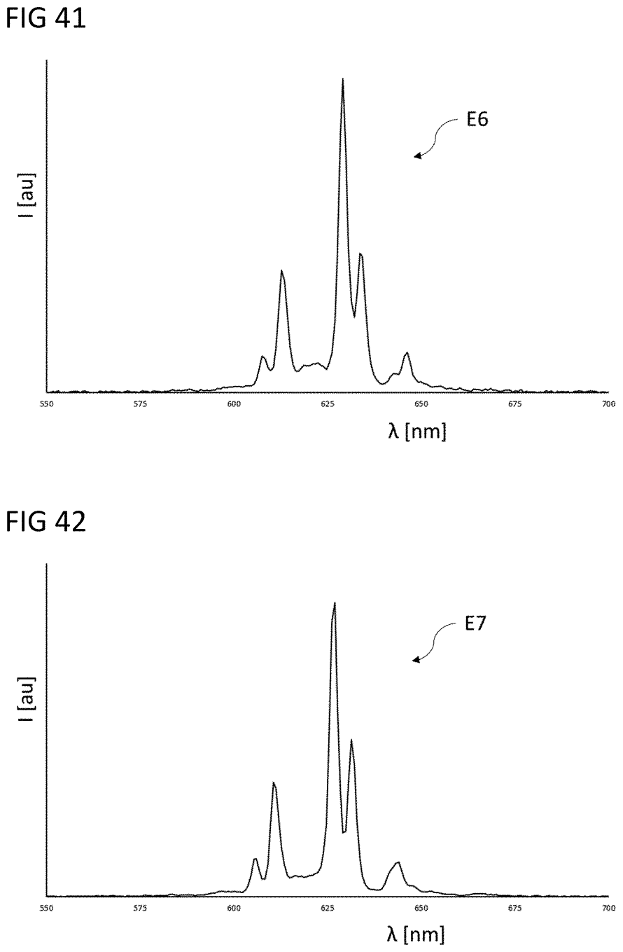

FIG. 41 shows an emission spectrum E6 of the working example CaPbF₆:Mn of the luminophore 1. The emission peak having the highest intensity has an emission maximum λₘₐₓ at 629.1 nm. A dominant wavelength λ_{D} is 618.6 nm. The emission of CaPbF₆:Mn is short-wave by about 2 nm compared to K₂SiF₆, and hence shifted toward the region of higher eye sensitivity (not shown), which results in a spectral gain. The effect of this is that the luminophore, compared to K₂SiF₆, has a gain of 5% in luminous efficacy of radiation. Advantageously, higher spectral efficiencies in LEDs are thus possible, for example, in LEDs for general lighting and display backlighting.

FIG. 42 shows an emission spectrum E6 of the working example SrSnF₆:Mn of the luminophore 1. The emission peak having the highest intensity has an emission maximum λₘₐₓ at 626.6 nm. A dominant wavelength λ_{D} is 617.2 nm. The emission of SrSnF₆:Mn is short-wave by about 4 nm compared to K₂SiF₆, and hence shifted toward the region of higher eye sensitivity (not shown), which results in a spectral gain. The effect of this is that the luminophore, compared to K₂SiF₆, has a gain of 13% in luminous efficacy of radiation. Advantageously, higher spectral efficiencies in LEDs are thus possible, for example, in LEDs for general lighting and display backlighting.

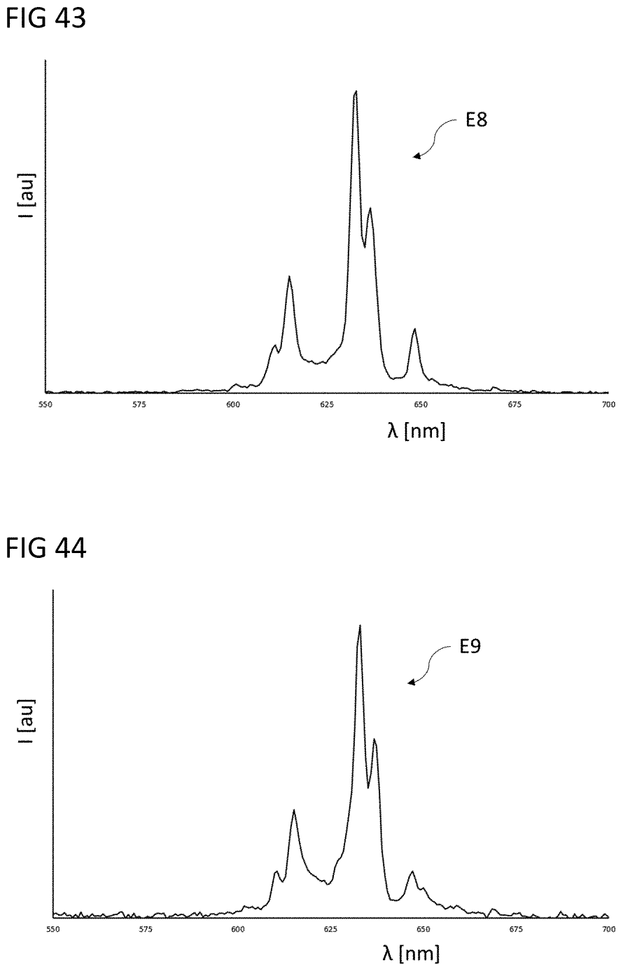

FIG. 43 shows an emission spectrum E8 of the working example BaPbF₆:Mn of the luminophore 1. The emission peak having the highest intensity has an emission maximum λₘₐₓ at 632.5 nm. A dominant wavelength λ_{D} is 620.6 nm.

FIG. 44 shows an emission spectrum E9 of the working example BaPbF₆:Mn of the luminophore 1. The emission peak having the highest intensity has an emission maximum λₘₐₓ at 632.6 nm. A dominant wavelength λ_{D} is 615.5 nm.

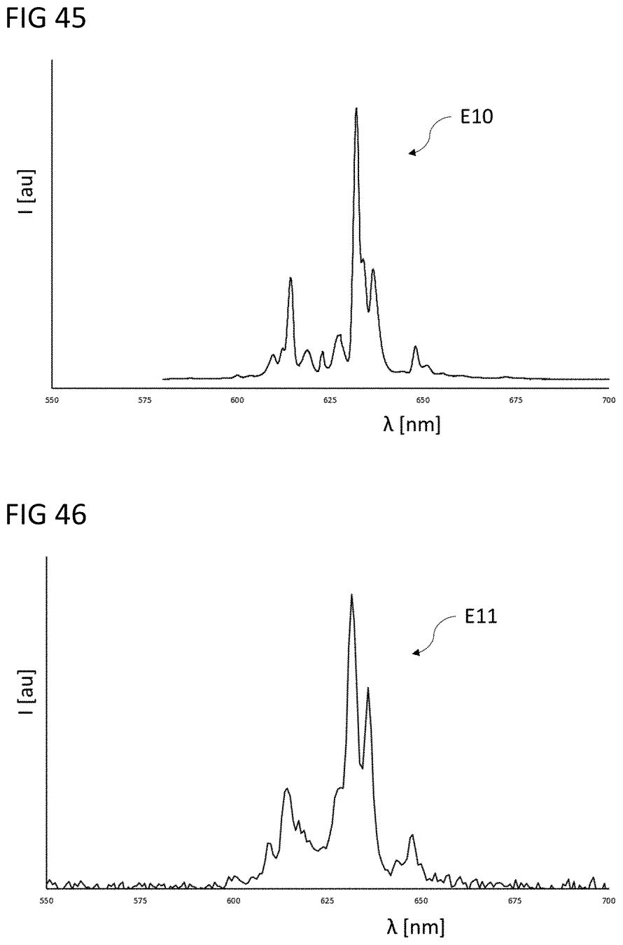

FIG. 45 shows an emission spectrum E10 of the working example MgGeF₆:Mn of the luminophore 1. The emission peak having the highest intensity has an emission maximum λₘₐₓ at 632 nm. A dominant wavelength λ_{D} is 614.5 nm. The emission maximum is in the region of the comparative luminophore K₂SiF₆:Mn and is thus suitable, for example, as an alternative luminophore in LEDs for general lighting and display backlighting.

FIG. 46 shows an emission spectrum E11 of the working example CdPbF₆:Mn of the luminophore 1. The emission peak having the highest intensity has an emission maximum λₘₐₓ at 631.5 nm. A dominant wavelength λ_{D} is 615.7 nm. The emission of CdPbF₆:Mn, compared to that of K₂SiF₆:Mn, has a higher magnitude in the region of 625 nm, as a result of which more photons are emitted in the region of higher eye sensitivity (not shown). The effect of this is that the luminophore, compared to K₂SiF₆, has a gain of 2% in luminous efficacy of radiation.

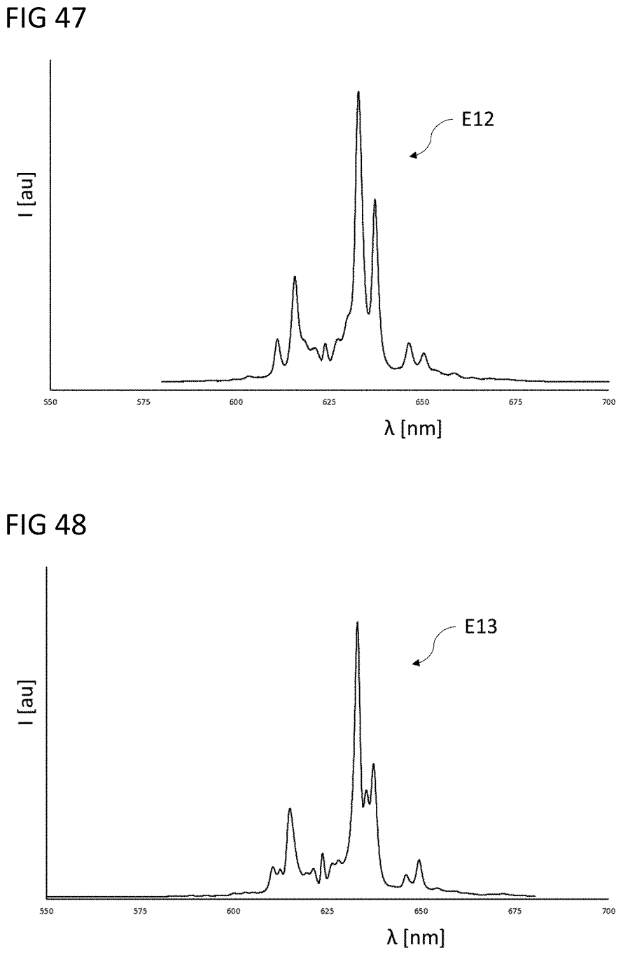

FIG. 47 shows an emission spectrum E12 of the working example ZnPbF₆:Mn of the luminophore 1. The emission peak having the highest intensity has an emission maximum λₘₐₓ at 632.8 nm. A dominant wavelength λ_{D} is 616.6 nm.

FIG. 48 shows an emission spectrum E13 of the working example MgPbF₆:Mn of the luminophore 1. The emission peak having the highest intensity has an emission maximum λₘₐₓ at 633 nm. A dominant wavelength λ_{D} is 613.3 nm. The emission of MgPbF₆:Mn and the comparative luminophore K₂SiF₆:Mn are almost at the same position in the spectrum (not shown). The luminous efficacy of radiation is in the region of the comparative luminophore K₂SiF₆:Mn. Thus, MgPbF₆:Mn is suitable, for example, as an alternative luminophore in LEDs for general lighting and display backlighting.

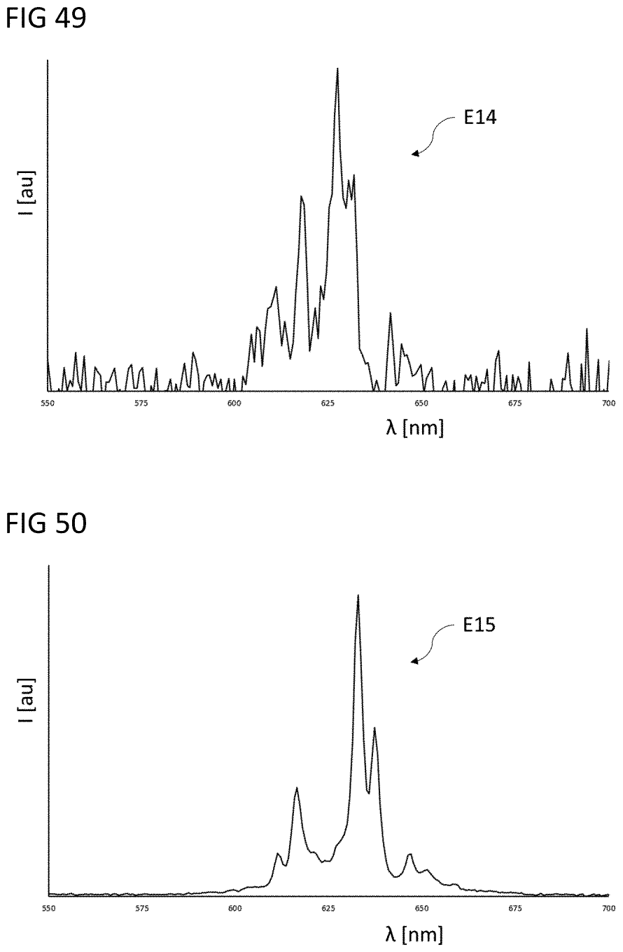

FIG. 49 shows an emission spectrum E14 of the working example CdHfF₆:Mn of the luminophore 1. The emission peak having the highest intensity has an emission maximum λₘₐₓ at 627.3 nm. A dominant wavelength λ_{D} is 609.9 nm. The emission of CdHfF₆:Mn is short-wave by about 3 nm compared to K₂SiF₆, and hence shifted toward the region of higher eye sensitivity (not shown), which results in a spectral gain. Advantageously, higher spectral efficiencies in LEDs are thus possible in LEDs for general lighting and display backlighting.

FIG. 50 shows an emission spectrum E15 of the working example ZnZrF₆:Mn of the luminophore 1. The emission peak having the highest intensity has an emission maximum λₘₐₓ at 632.8 nm. A dominant wavelength λ_{D} is 616.5 nm.

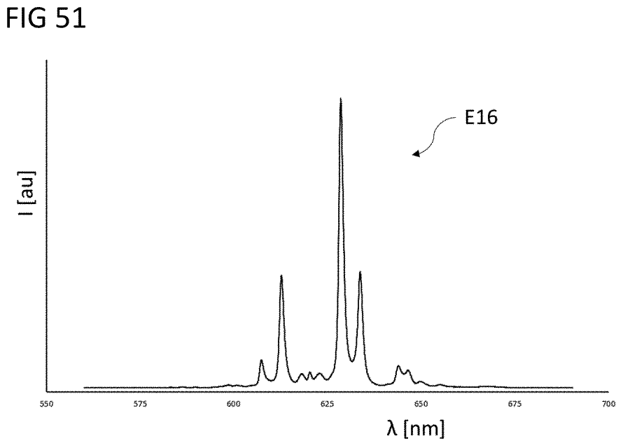

FIG. 51 shows an emission spectrum E16 of the working example CaSnF₆:Mn of the luminophore 1. The emission peak having the highest intensity has an emission maximum λₘₐₓ at 628.5 nm. A dominant wavelength λ_{D} is 609 nm. The emission of SrSnF₆:Mn is short-wave by about 2 nm compared to K₂SiF₆, and hence shifted toward the region of higher eye sensitivity (not shown), which results in a spectral gain. The effect of this is that the luminophore, compared to K₂SiF₆, has a gain of almost 13% in luminous efficacy of radiation. Advantageously, higher spectral efficiencies in LEDs are thus possible in LEDs for general lighting and display backlighting.

The features and working examples described in conjunction with the figures may be combined with one another in further working examples, even though not all combinations are described explicitly. In addition, working examples described in conjunction with the figures may alternatively or additionally have further features according to the description in the general part.

The invention is not limited to the working examples by the description with reference thereto. Instead, the invention encompasses any new feature and any combination of features, which especially include any combination of features in the claims, even if this feature of this combination itself is not explicitly specified in the claims or working examples.

### LIST OF REFERENCE NUMERALS

1 luminophore
2 AX₆ octahedron
3 EX₆ octahedron
4 vertex
5 radiation-emitting component
6 semiconductor chip
7 radiation exit face
8 conversion element
9 housing
10 recess
11 encapsulant
I intensity
au arbitrary unit
SP simulated powder diffractogram
P1 powder diffractogram of CaZrF₆:Mn
P2 powder diffractogram of CaHfF₆:Mn
P3 powder diffractogram of SrTiF₆:Mn
P4 powder diffractogram of ZnHfF₆:Mn
R1 Rietveld refinement of CaZrF₆:Mn
R2 Rietveld refinement of CaHfF₆:Mn
R4 Rietveld refinement of ZnHfF₆:Mn
R5 Rietveld refinement of CaGeF₆:Mn
R6 Rietveld refinement of CaPbF₆:Mn
R7 Rietveld refinement of SrSnF₆:Mn
R8 Rietveld refinement of BaPbF₆:Mn
R9 Le Bail refinement of ZnSnF₆:Mn
R10 Le Bail refinement of MgGeF₆:Mn
R11 Le Bail refinement of CdPbF₆:Mn
R12 Rietveld refinement of ZnPbF₆:Mn
R13 Le Bail refinement of MgPbF₆:Mn
R14 Le Bail refinement of CdHfF₆:Mn
R15 Rietveld refinement of ZnZrF₆:Mn
R16 Rietveld refinement of CaSnF₆:Mn
G1 measured reflection positions
G2 calculated powder diffractogram
G3 difference diagram
G4 calculated reflection position
G5 calculated reflection position of secondary phases
G6 calculated reflection position of secondary phases
A1 excitation spectrum of CaZrF₆:Mn
A2 excitation spectrum of CaHfF₆:Mn
A3 excitation spectrum of SrTiF₆:Mn
E1 emission spectrum of CaZrF₆:Mn
E2 emission spectrum of CaHfF₆:Mn
E3 emission spectrum of SrTiF₆:Mn
E4 emission spectrum of ZnHfF₆:Mn
E5 emission spectrum of CaGeF₆:Mn
E6 emission spectrum of CaPbF₆:Mn
E7 emission spectrum of SrSnF₆:Mn
E8 emission spectrum of BaPbF₆:Mn
E9 emission spectrum of ZnSnF₆:Mn
E10 emission spectrum of MgGeF₆:Mn
E11 emission spectrum of CdPbF₆:Mn
E12 emission spectrum of ZnPbF₆:Mn
E13 emission spectrum of MgPbF₆:Mn
E14 emission spectrum of CdHfF₆:Mn
E15 emission spectrum of ZnZrF₆:Mn
E16 emission spectrum of CaSnF₆:Mn
E-VB emission spectrum of the comparative example K₂SiF₆
SE1 simulated LED spectrum with CaZrF₆:Mn
SE2 simulated LED spectrum with CaHfF₆:Mn
S-VB simulated LED spectrum with the comparative example K₂SiF₆
S1 process step 1
S2 process step 2
S3 process step 3
LE1 relative luminous efficacy of radiation of CaZrF₆:Mn
LE2 relative luminous efficacy of radiation of CaHfF₆:Mn
LE-VB relative luminous efficacy of radiation of the comparative example K₂SiF₆
Rₐ color rendering index

1. A luminophore having the general formula A_{z}EₑX₆:RE where
A is selected from Ca, Sr, Ba, Zn, Mg, Cd, or combinations thereof,
E is Pb,
X is selected from F, Cl, Br, I, or combinations thereof,
RE is selected from activator elements,
0.9≤z≤1.1, and
0.9≤e≤1.1.

2. (canceled)

3. (canceled)

4. (canceled)

5. (canceled)

6. A luminophore having the general formula A_{z}EₑX₆:RE where
A is selected from Ca, Sr, Zn, Mg, Cd, or combinations thereof,
E is selected from Ti, Zr, Hf, Ge, Sn, Pb, or combinations thereof,
X is selected from F, Cl, Br, I, or combinations thereof,
RE is selected from activator elements,
0.9≤z≤1.1,
0.9≤e≤1.1, and
wherein the luminophore has a host lattice comprising AX₆ octahedra and EX₆ octahedra that are linked via common X atoms.

7. The luminophore as claimed in claim 6, wherein
E is selected from Ti, Zr, or combinations thereof.

8. The luminophore as claimed in claim 6,
wherein RE is selected from Mn, Cr, Ni, Eu, Cr, or combinations thereof.

9. The luminophore as claimed in claim 6,
wherein a local maxima in the excitation spectrum ranges from 320 nanometers to 420 nanometers inclusive, and from 430 nanometers to 550 nanometers inclusive.

10. The luminophore as claimed in claim 6,
wherein an emission spectrum has a multitude of emission peaks ranging from 600 nanometers to 700 nanometers.

11. The luminophore as claimed in claim 6, wherein a half-height width of an emission peak ranges from 1 nanometer to 10 nanometers inclusive.

12. The luminophore as claimed in claim 6,
wherein an emission maximum of an emission peak ranges from 625 nanometers to 633 nanometers inclusive.

13. The luminophore as claimed in claim 6,
wherein a dominant wavelength (λ_{D}) ranges from 610 nanometers to 618 nanometers inclusive.

14. A process for producing a luminophore having the general formula A_{z}EₑX₆:RE where
A is selected from the group of divalent elements,
E is selected from the group of tetravalent elements,
X is selected from the group of monovalent elements,
RE is selected from activator elements,
0.9≤z≤1.1 and
0.9≤e≤1.1;
wherein the process comprises:
providing a stoichiometric composition of reactants;
homogenizing the reactants to produce a reaction mixture; and
heating the reaction mixture to a maximum temperature.

15. The process for producing a luminophore as claimed in claim 14,
wherein the heating takes place in an F₂ stream.

16. (canceled)

17. A radiation-emitting component comprising:
a semiconductor chip configured to emit electromagnetic radiation in a first wavelength range in operation; and
a conversion element including a luminophore as claimed in claim 6 configured to convert electromagnetic radiation in the first wavelength range to electromagnetic radiation in a second wavelength range.

18. The radiation-emitting component as claimed in claim 17,
wherein the conversion element comprises a second luminophore configured to convert electromagnetic radiation in the first wavelength range to electromagnetic radiation in a third wavelength range.
